(19) United States
(12) Patent Application Publication
(10) Pub. No.: US 2024/0055448 A1
(43) Pub. Date: Feb. 15, 2024

(54) PHOTOELECTRIC CONVERSION ELEMENT AND IMAGING DEVICE

(71) Applicant: SONY SEMICONDUCTOR SOLUTIONS CORPORATION, KANAGAWA (JP)

(72) Inventors: HIDEKI MINARI, KANAGAWA (JP); RYOSUKE MATSUMOTO, KANAGAWA (JP)

(21) Appl. No.: 18/549,647

(22) PCT Filed: Mar. 8, 2022
(86) PCT No.: PCT/JP2022/010109

§ 371 Date: Sep. 8, 2023

(30) Foreign Application Priority Data
Mar. 17, 2021 (JP) 2021-043366

(51) Int. Cl. H01L 27/146

(52) U.S. Cl. CPC H01L 27/1461; H01L 27/14649; H01L 27/14623; H01L 27/14627; H01L 27/14694; H01L 27/14689; G01S 17/08

(57) ABSTRACT

There is provide a photoelectric conversion element and an imaging device, in which image quality is capable of being improved. The photoelectric conversion element includes: a photoelectric conversion layer including a compound semiconductor material; a mesa portion disposed on a part of an upper surface side of the photoelectric conversion layer and including a compound semiconductor material having band gap energy larger than the band gap energy of the photoelectric conversion layer; a first electrode disposed on the mesa portion and configured to read charge photoelectrically converted in the photoelectric conversion layer via the mesa portion; and a transfer gate disposed to face a part of the upper surface side of the photoelectric conversion layer and at least a part of a sidewall of the mesa portion.

### TECHNICAL FIELD

The present disclosure relates to a photoelectric conversion element and an imaging device.

### BACKGROUND ART

An image sensor (also referred to as an infrared sensor) having sensitivity to an infrared region is widely used for a monitoring camera and the like (refer to Patent Document 1). In this type of image sensor of the related art, a pn junction formed above a photoelectric conversion layer is directly connected to a sense node, and there is a problem that image quality deteriorates due to an influence of interface generation noise such as a dark current.

In order to solve this problem, there has been proposed a photoelectric conversion element in which a material having band gap energy larger than band gap energy of a photoelectric conversion layer is disposed above the photoelectric conversion layer, and a pn junction is formed by this material to suppress generation of the dark current (refer to Patent Document 2).

### CITATION LIST

### Patent Document

Patent Document 1: Japanese Patent Application Laid-Open No. 2009-283603
Patent Document 2: WO 2018/212175 A1

### SUMMARY OF THE INVENTION

### Problems to be Solved by the Invention

The photoelectric conversion element of Patent Document 2 can suppress generation of the dark current at the pn junction described above, but there is a problem that a band offset formed at an interface between layers having different band gap energy serves as a transfer barrier and an afterimage is generated.

Furthermore, in both Patent Documents 1 and 2, since a photocurrent always flows from the photoelectric conversion layer toward the sense node, there is a problem that a reset potential before an optical signal is input cannot be accurately acquired. Therefore, correlated double sampling (CDS) for detecting a difference between a potential at the time of inputting an optical signal and a reset potential cannot be performed, and image quality deteriorates.

Accordingly, an object of the present disclosure is to provide a photoelectric conversion element and an imaging device, in which image quality is capable of being improved.

### Solutions to Problems

In order to solve the above-described problems, according to an aspect of the present disclosure, there is provided a photoelectric conversion element including:
a photoelectric conversion layer including a compound semiconductor material;
a mesa portion disposed on a part of an upper surface side of the photoelectric conversion layer and including a compound semiconductor material having band gap energy larger than the band gap energy of the photoelectric conversion layer;
a first electrode disposed on the mesa portion and configured to read charge photoelectrically converted in the photoelectric conversion layer via the mesa portion; and
a transfer gate disposed to face a part of the upper surface side of the photoelectric conversion layer and at least a part of a sidewall of the mesa portion.

The mesa portion may include
a first semiconductor layer of a first conductivity type, and
a second semiconductor layer of a second conductivity type, which is stacked on the first semiconductor layer and connected to the first electrode, and
the first electrode may read charge of a second conductivity type, which is generated by photoelectric conversion in the photoelectric conversion layer.

There may be further provided a third semiconductor layer of a second conductivity type, which is disposed between the first electrode and the second semiconductor layer and has band gap energy smaller than the band gap energy of the first semiconductor layer and the band gap energy of the second semiconductor layer.

There may be further provided:
a fourth semiconductor layer disposed on the upper surface side of the photoelectric conversion layer and including an impurity of a first conductivity type;
a fifth semiconductor layer disposed on a lower surface side of the photoelectric conversion layer and including the impurity of the first conductivity type; and
a first diffusion layer disposed on a sidewall of the photoelectric conversion layer and including the impurity of the first conductivity type.

The fourth semiconductor layer may be a semiconductor layer of a first conductivity type, which has band gap energy larger than the band gap energy of the photoelectric conversion layer.

The fifth semiconductor layer may be disposed across a plurality of pixels without being separated at a boundary between the pixels.

There may be further provided a second electrode disposed in a region where the mesa portion is not disposed on the upper surface side of the photoelectric conversion layer and electrically connected to the fifth semiconductor layer.

There may be further provided an insulation film disposed along a boundary region between adjacent pixels of the photoelectric conversion layer.

There may be further provided a light-shielding metal layer disposed along a boundary region between adjacent pixels of the photoelectric conversion layer.

There may be further provided a second diffusion layer disposed along a boundary region between adjacent pixels of the photoelectric conversion layer and including an impurity of a first conductivity type.

The photoelectric conversion layer may have a lower concentration of an impurity of a first conductivity type on the upper surface side closer to the mesa portion and the transfer gate.

The transfer gate may be disposed to face an entire region where the mesa portion is not disposed on the upper surface side of the photoelectric conversion layer.

The first electrode may be disposed along a center portion, a corner portion, or one side of a pixel including the photoelectric conversion layer, the mesa portion, and the transfer gate.

There may be further provided a third diffusion layer including an impurity of a first conductivity type, which is disposed in a region where the mesa portion is not disposed on the upper surface side of the photoelectric conversion layer.

There may be further provided a fourth diffusion layer including an impurity of a first conductivity type, which is disposed on at least a part of the sidewall of the mesa portion.

There may be further provided an insulation film disposed so as to cover at least a part of a periphery of the photoelectric conversion layer and mesa portion and having fixed charge having the same polarity as that of the charge read by the first electrode.

There may be further provided an optical member disposed on a lower surface side of the photoelectric conversion layer and configured to condense light on the photoelectric conversion layer.

One first electrode may be shared by a plurality of pixels.

There may be further provided a plurality of pixels each including the photoelectric conversion layer, the mesa portion, and the first electrode, the plurality of pixels being disposed adjacent to each other,
in which charge photoelectrically converted in the photoelectric conversion layer may be movable between the plurality of pixels, and a plurality of the first electrodes in the plurality of pixels may sequentially read the charge or the plurality of first electrodes may read the charge in parallel.

According to another aspect of the present disclosure, there is provided an imaging device including a pixel array unit including a plurality of pixels,
in which each of the plurality of pixels includes:
a photoelectric conversion layer including a compound semiconductor material;
a mesa portion disposed on a part of an upper surface side of the photoelectric conversion layer and having band gap energy larger than the band gap energy of the photoelectric conversion layer;
a first electrode disposed on the mesa portion and configured to read charge photoelectrically converted in the photoelectric conversion layer via the mesa portion; and
a transfer gate disposed to face a part of the upper surface side of the photoelectric conversion layer and at least a part of a sidewall of the mesa portion.

### BRIEF DESCRIPTION OF DRAWINGS

FIG. 1 is a cross-sectional view of a photoelectric conversion element according to a first embodiment.

FIG. 2 is an energy band diagram of a photoelectric conversion element 1 of FIG. 1.

FIG. 3A is a cross-sectional view of a photoelectric conversion element according to a first comparative example.

FIG. 3B is a cross-sectional view of a photoelectric conversion element according to a second comparative example.

FIG. 3C is an energy band diagram of a photoelectric conversion element of FIG. 3B.

FIG. 4 illustrates a cross-sectional view and plan view of a photoelectric conversion element according to the present embodiment.

FIG. 5A is a cross-sectional view illustrating a process of manufacturing a photoelectric conversion element according to the first embodiment.

FIG. 5B is a process cross-sectional view subsequent to FIG. 5A.

FIG. 5C is a process cross-sectional view subsequent to FIG. 5B.

FIG. 5D is a process cross-sectional view subsequent to FIG. 5C.

FIG. 5E is a process cross-sectional view subsequent to FIG. 5D.

FIG. 5F is a process cross-sectional view subsequent to FIG. 5E.

FIG. 5G is a process cross-sectional view subsequent to FIG. 5F.

FIG. 5H is a process cross-sectional view subsequent to FIG. 5G.

FIG. 5I is a process cross-sectional view subsequent to FIG. 5H.

FIG. 5J is a process cross-sectional view subsequent to FIG. 5I.

FIG. 5K is a process cross-sectional view subsequent to FIG. 5J.

FIG. 5L is a process cross-sectional view subsequent to FIG. 5K.

FIG. 5M is a process cross-sectional view subsequent to FIG. 5L.

FIG. 5N is a process cross-sectional view subsequent to FIG. 5M.

FIG. 5O is a process cross-sectional view subsequent to FIG. 5N.

FIG. 5P is a process cross-sectional view subsequent to FIG. 5O.

FIG. 6 is a cross-sectional view of a photoelectric conversion element according to a second embodiment.

FIG. 7 is a cross-sectional view of a photoelectric conversion element according to a third embodiment.

FIG. 8A is a cross-sectional view of a photoelectric conversion element according to a fourth embodiment.

FIG. 8B is a plan view of a photoelectric conversion element according to the fourth embodiment.

FIG. 9A is a cross-sectional view of a photoelectric conversion element according to a fifth embodiment.

FIG. 9B is a plan view of a photoelectric conversion element according to the fifth embodiment.

FIG. 10A is a cross-sectional view of a photoelectric conversion element according to a sixth embodiment.

FIG. 10B is a plan view of a photoelectric conversion element according to the sixth embodiment.

FIG. 11 is a cross-sectional view of a photoelectric conversion element according to a seventh embodiment.

FIG. 12 is a cross-sectional view of a photoelectric conversion element according to an eighth embodiment.

FIG. 13 is a cross-sectional view of a photoelectric conversion element according to a ninth embodiment.

FIG. 14 is a cross-sectional view of a photoelectric conversion element according to a tenth embodiment.

FIG. 15 is a cross-sectional view of a photoelectric conversion element according to an eleventh embodiment.

FIG. 16 is a cross-sectional view of a photoelectric conversion element according to a twelfth embodiment.

FIG. 17 is a cross-sectional view illustrating an example in which a light-shielding metal layer is disposed in a pixel boundary region of the photoelectric conversion element in FIG. 15.

FIG. 18A is a cross-sectional view of a photoelectric conversion element according to a thirteenth embodiment.

FIG. 18B is a plan view of a photoelectric conversion element according to the thirteenth embodiment as viewed from above.

FIG. 19A is a cross-sectional view of a first modification example of the photoelectric conversion element in FIG. 18A.

FIG. 19B is a plan view of the first modification example.

FIG. 20A is a cross-sectional view of a second modification example of the photoelectric conversion element in FIG. 18A.

FIG. 20B is a plan view of the second modification example.

FIG. 21 is a cross-sectional view of a photoelectric conversion element according to a fourteenth embodiment.

FIG. 22 is a cross-sectional view of a photoelectric conversion element according to a fifteenth embodiment.

FIG. 23 is a cross-sectional view of a photoelectric conversion element according to a sixteenth embodiment.

FIG. 24A is a cross-sectional view of a photoelectric conversion element according to a seventeenth embodiment.

FIG. 24B is a plan view of a photoelectric conversion element according to the seventeenth embodiment.

FIG. 24C is a plan view of a photoelectric conversion element according to the seventeenth embodiment.

FIG. 25A is a cross-sectional view of a photoelectric conversion element according to a modification example in FIG. 24A.

FIG. 25B is a plan view of a photoelectric conversion element according to a modification example in FIG. 24B.

FIG. 25C is a plan view of a photoelectric conversion element according to a modification example in FIG. 24C.

FIG. 26A is a cross-sectional view of a photoelectric conversion element according to an eighteenth embodiment.

FIG. 26B is a plan view of a photoelectric conversion element according to the eighteenth embodiment.

FIG. 26C is a plan view of a first modification example in FIG. 26B.

FIG. 26D is a plan view of a second modification example in FIG. 26B.

FIG. 26E is a plan view of a third modification example in FIG. 26B.

FIG. 27A is a cross-sectional view of a photoelectric conversion element according to a nineteenth embodiment.

FIG. 27B is a plan view of a photoelectric conversion element according to the nineteenth embodiment.

FIG. 27C is a plan view of a first modification example in FIG. 27B.

FIG. 27D is a plan view of a second modification example in FIG. 27B.

FIG. 27E is a plan view of a third modification example in FIG. 27B.

FIG. 28A is a cross-sectional view of a photoelectric conversion element according to a twentieth embodiment.

FIG. 28B is a plan view of a photoelectric conversion element according to the twentieth embodiment.

FIG. 28C is a plan view of a first modification example in FIG. 28B.

FIG. 28D is a plan view of a second modification example in FIG. 28B.

FIG. 29A is a cross-sectional view of a photoelectric conversion element according to a twenty-first embodiment.

FIG. 29B is a plan view of a photoelectric conversion element according to the twenty-first embodiment.

FIG. 29C is a plan view of a first modification example in FIG. 29B.

FIG. 29D is a plan view of a second modification example in FIG. 29B.

FIG. 29E is a plan view of a third modification example in FIG. 29B.

FIG. 30A is a cross-sectional view of a photoelectric conversion element according to a twenty-second embodiment.

FIG. 30B is a plan view of a photoelectric conversion element according to the twenty-second embodiment.

FIG. 30C is a plan view of a modification example in FIG. 30B.

FIG. 30D is a plan view of a modification example in FIG. 30B.

FIG. 30E is a plan view of a modification example in FIG. 30B.

FIG. 31A is a cross-sectional view of a photoelectric conversion element according to a twenty-third embodiment.

FIG. 31B is a plan view of a photoelectric conversion element according to the twenty-third embodiment.

FIG. 31C is a plan view of a modification example in FIG. 31B.

FIG. 32A is a cross-sectional view of a photoelectric conversion element according to a twenty-fourth embodiment.

FIG. 32B is a plan view of a photoelectric conversion element according to the twenty-fourth embodiment.

FIG. 32C is a plan view of a first modification example in FIG. 32B.

FIG. 32D is a plan view of a second modification example in FIG. 32B.

FIG. 32E is a plan view of a third modification example in FIG. 32B.

FIG. 33A is a cross-sectional view of a photoelectric conversion element according to a twenty-fifth embodiment.

FIG. 33B is a plan view of a photoelectric conversion element according to the twenty-fifth embodiment.

FIG. 33C is a plan view of a first modification example in FIG. 33B.

FIG. 33D is a plan view of a second modification example in FIG. 33B.

FIG. 33E is a plan view of a third modification example in FIG. 33B.

FIG. 34A is a cross-sectional view of a photoelectric conversion element according to a twenty-sixth embodiment.

FIG. 34B is a plan view of a photoelectric conversion element according to the twenty-sixth embodiment.

FIG. 34C is a plan view of a photoelectric conversion element according to the twenty-sixth embodiment.

FIG. 35 is a block diagram illustrating an overall basic configuration of a CMOS image sensor which is an example of an imaging device.

FIG. 36 is a schematic perspective view of a semiconductor device on which the CMOS image sensor of FIG. 35 is mounted.

FIG. 37 is a block diagram illustrating an example of a schematic configuration of a vehicle control system.

FIG. 38 is a diagram of assistance in explaining an example of installation positions of an outside-vehicle information detecting section and imaging section.

### MODE FOR CARRYING OUT THE INVENTION

Embodiments of a photoelectric conversion element and an imaging device will be described below with reference to the drawings. Although principal components of the photoelectric conversion element and imaging device will be mainly described below, the photoelectric conversion element and the imaging device may include components and functions that are not illustrated or described. The following description does not exclude components and functions that are not illustrated or described.

### First Embodiment

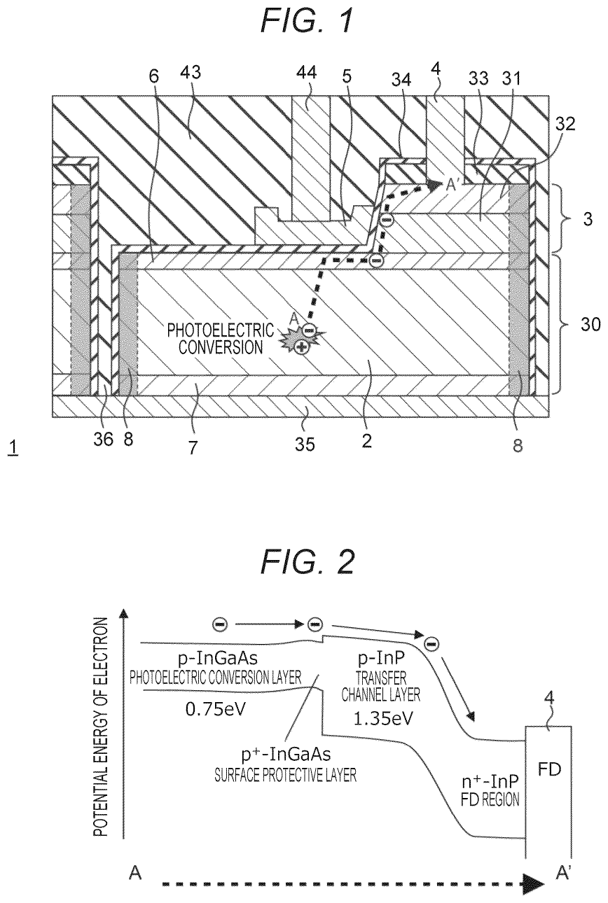

FIG. 1 is a cross-sectional view of a photoelectric conversion element 1 according to a first embodiment. An imaging device is formed by disposing a plurality of photoelectric conversion elements 1 in FIG. 1 in a two-dimensional direction. The photoelectric conversion element 1 of FIG. 1 is applied to, for example, an infrared sensor using a compound semiconductor material such as an III-V semiconductor. The photoelectric conversion element 1 of FIG. 1 can perform photoelectric conversion on light having a wavelength, for example, between a visible region (equal to or greater than 380 nm and less than 780 nm) and a short infrared region (equal to or greater than 780 nm and less than 2400 nm).

The photoelectric conversion element 1 of FIG. 1 includes a photoelectric conversion layer 2, a mesa portion 3, an FD electrode 4, and a transfer gate 5.

The photoelectric conversion layer 2 contains the compound semiconductor material as described above. There is a plurality of candidates for the compound semiconductor material of the photoelectric conversion layer 2, and a typical example thereof is p-type InGaAs (indium gallium arsenide). In FIG. 1, the lower surface side of the photoelectric conversion layer 2 is a light irradiation surface side. For example, a p⁺-InGaAs (indium gallium arsenide) layer 6 may be epitaxially grown on the upper surface side of the photoelectric conversion layer 2. Furthermore, on the lower surface side of the photoelectric conversion layer 2, for example, a p⁺-InP (indium phosphide) layer 7 may be epitaxially grown. Moreover, on the sidewall of the photoelectric conversion layer 2, for example, a p-type impurity diffusion layer 8 having a high concentration may be formed. A typical example of the p-type impurity is zinc (Zn). In the present description, the photoelectric conversion layer 2, the p⁺-InGaAs layer 6, the p⁺-InP layer 7, and the diffusion layer 8 are collectively referred to as a photoelectric conversion portion 30.

As described above, by surrounding the periphery of the photoelectric conversion layer 2 with the layers 6 to 8 containing a high-concentration p-type impurity, it is possible to prevent an electron generated in the photoelectric conversion layer 2 from moving toward the surface of the photoelectric conversion layer 2 to leak, and to suppress liberation of noise charge on the surface (interface) of the photoelectric conversion layer 2.

An example of the compound semiconductor material of the photoelectric conversion layer 2 includes an III-V semiconductor containing at least one of indium (In), gallium (Ga), aluminum (Al), arsenic (As), phosphorus (P), antimony (Sb), nitrogen (N), silicon (Si), carbon (C), or germanium (Ge). Specific examples thereof include indium gallium arsenide phosphorus (InGaAsP), indium arsenide antimony (InAsSb), indium gallium phosphorus (InGaP), gallium arsenide antimony (GaAsSb), indium aluminum arsenic (InAlAs), silicon carbide (SiC), and silicon germanium (SiGe), in addition to the InGaAs described above. The doping density of the photoelectric conversion layer 2 is desirably, for example, 1×10¹⁶ cm⁻³, and ranges from 1×10¹³ cm⁻³ to 1×10¹⁸ cm⁻³. When the doping density of the photoelectric conversion layer 2 is higher than 1×10¹⁷ cm⁻³, the loss probability due to recombination of signal charges generated by photoelectric conversion increases, and the quantum efficiency decreases.

At least a part of the photoelectric conversion layer 2 may be doped with an impurity. The impurity may be only required to be a material that functions as a dopant in the compound semiconductor. Examples of the impurity include zinc (Zn), magnesium (Mg), cadmium (Cd), beryllium (Be), silicon (Si), germanium (Ge), carbon (C), tin (Sn), lead (Pb), sulfur (S), tellurium (Te), phosphorus (P), boron (B), arsenic (As), indium (In), antimony (Sb), gallium (Ga), and aluminum (Al).

The thickness of the photoelectric conversion layer 2 is desirably, for example, about 3 μm, but may range from about 100 nm to about 100 μm. When the thickness of the photoelectric conversion layer 2 is too thin, the amount of light transmitted through the photoelectric conversion layer 2 increases, and there is a possibility that the quantum efficiency significantly decreases.

The mesa portion 3 is disposed on a part of the upper surface side of the photoelectric conversion layer 2 and contains a compound semiconductor material having band gap energy larger than the band gap energy of the photoelectric conversion layer 2. At least a part of the sidewall of the mesa portion 3 is disposed in a direction inclined from the normal direction of the upper surface of the photoelectric conversion layer 2.

The mesa portion 3 has a structure in which a first semiconductor layer 31 of a first conductivity type and a second semiconductor layer 32 of a second conductivity type are stacked from a side close to the photoelectric conversion layer 2. In a case where the first conductivity type is p-type, the second conductivity type is n-type. Examples of the first semiconductor layer 31 and second semiconductor layer 32 includes, for example, an III-V semiconductor containing at least one of indium (In), gallium (Ga), aluminum (Al), arsenic (As), phosphorus (P), antimony (Sb), nitrogen (N), silicon (Si), carbon (C), or germanium (Ge). Specific examples thereof include indium phosphide (InP), indium gallium arsenide phosphorus (InGaAsP), indium arsenide antimony (InAsSb), indium gallium phosphorus (InGaP), gallium arsenide antimony (GaAsSb), indium aluminum arsenic (InAlAs), silicon carbide (SiC), and silicon germanium (SiGe). The sum of the thickness of the first semiconductor layer 31 and the thickness of the second semiconductor layer 32 ranges from, for example, 100 nm to 3000 nm. In a case where the sum of the thickness of the first semiconductor layer 31 and the thickness of the second semiconductor layer 32 is less than 100 nm, a depletion layer formed near a pn junction formed near an interface between the first semiconductor layer 31 and the second semiconductor layer 32 is in contact with the FD electrode 4 and the photoelectric conversion layer 2, which may cause an increase in a dark current. When the sum of the thickness of the first semiconductor layer 31 and the thickness of the second semiconductor layer 32 exceeds 3000 nm, there is a possibility that the transfer efficiency of the read charge decreases.

The FD electrode 4 is in contact with the upper surface of the second semiconductor layer 32. Furthermore, an insulation film 33 is disposed around a contact portion between the second semiconductor layer 32 and the FD electrode 4. The material of the insulation film 33 is not limited, and is, for example, SiN.

As described above, in the photoelectric conversion element 1 according to the present embodiment, the pn junction does not exist inside the photoelectric conversion layer 2, and the pn junction is provided at the interface between the first semiconductor layer 31 and the second semiconductor layer 32 in the mesa portion 3 disposed on a part of the upper surface of the photoelectric conversion layer 2. Since the compound semiconductor material of the first semiconductor layer 31 and second semiconductor layer 32 in the mesa portion 3 has band gap energy larger than that of the compound semiconductor material of the photoelectric conversion layer 2, generation of the dark current at the pn junction is suppressed, and noise caused by the dark current can be reduced. As described above, the band offset occurs due to the difference in the band gap energy at the interface between the photoelectric conversion layer 2 and the mesa portion 3. However, the transfer gate 5 is disposed at a position facing the interface, and the voltage applied to the transfer gate 5 can lower the transfer barrier caused by the band offset and suppress the afterimage.

Furthermore, since the transfer gate 5 can control the transfer of the read charge to the FD electrode 4, the reset potential can be accurately detected, and the CDS operation can be performed.

The surfaces of the photoelectric conversion layer 2 and mesa portion 3 may be covered with a sealing insulation film 34. The sealing insulation film 34 is an insulation material such as SiN.

The transfer gate 5 is disposed to face a part of the upper surface side of the photoelectric conversion layer 2 and at least a part of the sidewall of the mesa portion 3. The above-described sealing insulation film 34 functions as a gate insulation film of the transfer gate 5. The transfer gate 5 includes a metal material such as copper (Cu), gold (Au), or aluminum (Al). The transfer gate 5 is disposed to face the photoelectric conversion layer 2 and is disposed to face at least the first semiconductor layer 31 in the mesa portion 3. The transfer gate 5 may be disposed so as to face not only the first semiconductor layer 31 in the mesa portion 3 but also the second semiconductor layer 32.

A transparent electrode 35 is disposed on the back surface side of the photoelectric conversion layer 2. Light is incident on the photoelectric conversion layer 2 through the transparent electrode 35. The transparent electrode 35 has a transparent conductive layer. For example, the transparent conductive layer has a transmittance of 50% or more for light having a wavelength of 1.6 μm. As a specific material of the transparent conductive layer, Indium Tin Oxide (ITO), In₂O₃—TiO₂ (ITiO), or the like can be used. The transparent electrode 35 may be shared by a plurality of pixels. In this case, the transparent electrode 35 is disposed across a plurality of the pixels without being separated at the boundary of the pixels.

FIG. 2 is an energy band diagram of the photoelectric conversion element 1 of FIG. 1, and illustrates the energy band from a location A in the photoelectric conversion layer 2 of FIG. 1 to a location A′ near the FD electrode 4. As illustrated in FIG. 2, in a case where the photoelectric conversion layer 2 is a p-InGaAs layer, the band gap energy is about 0.75 eV. Furthermore, in a case where the first semiconductor layer 31 in the mesa portion 3 is a p-InP layer, the band gap energy is about 1.35 eV. When an electron generated by photoelectric conversion moves from the photoelectric conversion layer 2 to the first semiconductor layer 31 in the mesa portion 3, a band offset occurs. However, when a positive voltage is applied to the transfer gate 5, the electron climbs over the band offset and is transferred to the first semiconductor layer 31 including p-InP. Thereafter, the electron passes through a depletion layer formed near the pn junction formed at the interface between the first semiconductor layer 31 and the second semiconductor layer 32 and reaches the FD electrode 4.

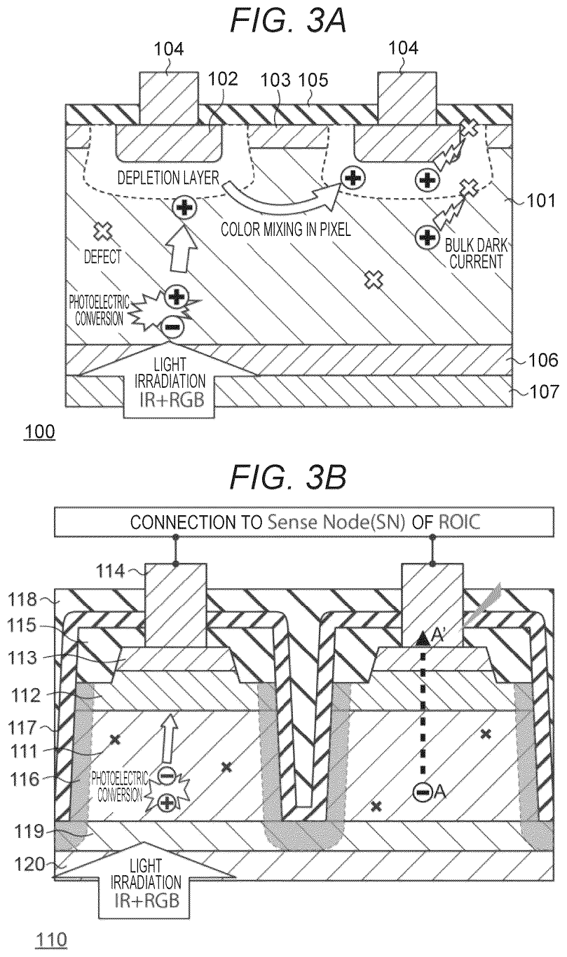

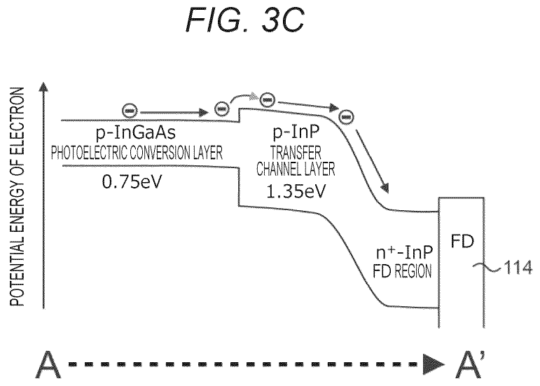

FIG. 3A is a cross-sectional view of a photoelectric conversion element 100 according to a first comparative example. For example, the photoelectric conversion element 1 of FIG. 3A includes a photoelectric conversion layer 101 including n-InGaAs, a Zn diffusion layer 102 and an n-InP layer 103, which are disposed on the upper surface side of the photoelectric conversion layer 101, an electrode 104 which is a sense node electrically connected to the Zn diffusion layer 102, and a SiN layer 105 disposed around the electrode 104. Furthermore, on the back surface side of the photoelectric conversion element 1, for example, an n⁺-InP layer 106 and a transparent electrode 107 are stacked.

In the photoelectric conversion element 100 of FIG. 3A, the pn junction formed on the upper surface side of the photoelectric conversion layer 101 has the same band gap energy as that of the photoelectric conversion layer 101, and thus the dark current is likely to be generated. Furthermore, since the pn junction is directly connected to the electrode 104, leakage is likely to occur. Moreover, since a photocurrent always flows through the electrode 104, the reset potential cannot be detected, and the CDS operation cannot be performed.

FIG. 3B is a cross-sectional view of a photoelectric conversion element 110 according to a second comparative example. In the photoelectric conversion element 1 of FIG. 3B, for example, a p-InP layer 112 and an n⁺-InP layer 113, which have band gap energy larger than the band gap energy of the photoelectric conversion layer 2, are stacked on a photoelectric conversion layer 111 including the p-InGaAs. The n⁺-InP layer 113 is in contact with an electrode 114, and a SiN layer 115 is disposed around the n⁺-InP layer 113.

Furthermore, a diffusion layer 116 is disposed on a sidewall portion of the photoelectric conversion layer 111, a coating film 117 such as Al₂O₃ is disposed on the diffusion layer 116, and a protective film 118 is disposed on the coating film 117. A p⁺-InP layer 119 is disposed on the back surface side of the photoelectric conversion layer 111, and a transparent electrode 120 is disposed on the p⁺-InP layer 119.

FIG. 3C is an energy band diagram of the photoelectric conversion element 110 of FIG. 3B, and illustrates the energy band from a location A in the photoelectric conversion layer 111 of FIG. 3B to a location A′ near the electrode 114. In the photoelectric conversion element 110 of FIG. 3B, when the electron generated in the p-InGaAs layer 111 reach the interface with the p-InP layer 112, the band offset acts as a barrier to prevent the transfer of the electron. Some electrons that have climbed over the band offset reach the electrode 114, which means that the photocurrent continues to flow at all times. That is, the photoelectric conversion element 110 in FIG. 3B cannot perform the CDS operation similarly to the photoelectric conversion element 100 in FIG. 3A.

The photoelectric conversion element 1 of FIG. 1 can solve the problem of the photoelectric conversion elements 100 and 110 of FIG. 3A and FIG. 3B. In the photoelectric conversion element 1 of FIG. 1, the mesa portion 3 having a pn junction is disposed above the photoelectric conversion layer 2 without having a pn junction inside the photoelectric conversion layer 2. In addition, the band gap energy of the first semiconductor layer 31 and the band gap energy of the second semiconductor layer 32 in the mesa portion 3 is made larger than the band gap energy of the photoelectric conversion layer 2. Thus, the dark current is less likely to be generated at the pn junction formed at the interface between the first semiconductor layer 31 and the second semiconductor layer 32 in the mesa portion 3. The band offset occurs at an interface between the photoelectric conversion layer 2 and the mesa portion 3. However, the transfer gate 5 is provided near the interface, and thus the transfer of the read charge is not affected by the band offset. Furthermore, since the transfer of the read charge can be controlled by the transfer gate 5, the reset potential in a state in which no optical signal is input can be accurately detected, and the CDS operation that cannot be performed in the photoelectric conversion element 1 of FIG. 3A and FIG. 3B can be performed.

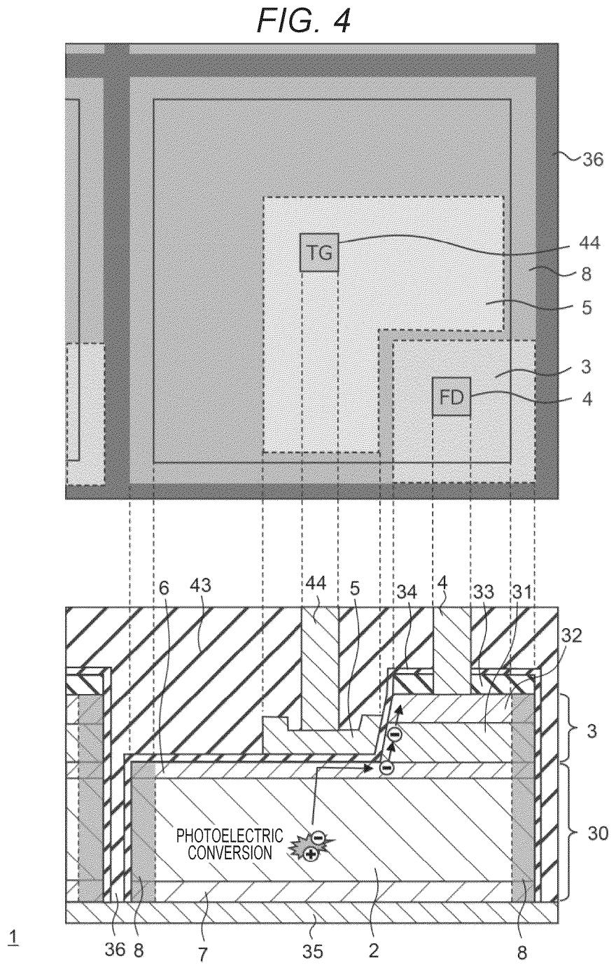

FIG. 4 illustrates a cross-sectional view and plan view of the photoelectric conversion element 1 according to the present embodiment. The cross-sectional view in FIG. 4 is the same as that of in FIG. 1. As illustrated in the plan view of FIG. 4, a pixel has, for example, a rectangular shape, the mesa portion 3 is disposed at, for example, a corner portion of the pixel, and the transfer gate 5 is disposed around the mesa portion 3. For example, an insulation layer 36 is disposed in a boundary region of the pixel, and the diffusion layer 8, in which a high-concentration p-type impurity (for example, Zn) is diffused, is disposed along the insulation layer 36.

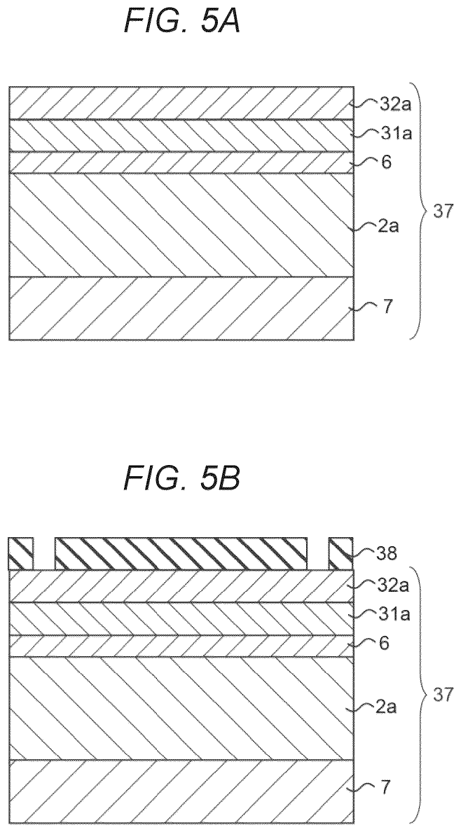

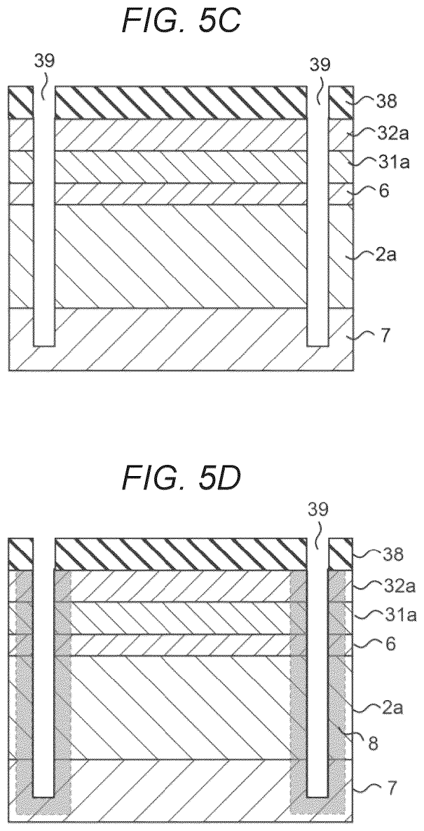

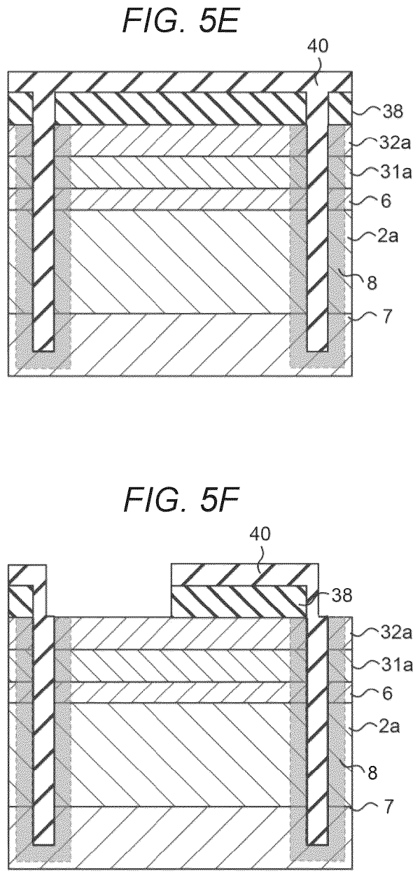

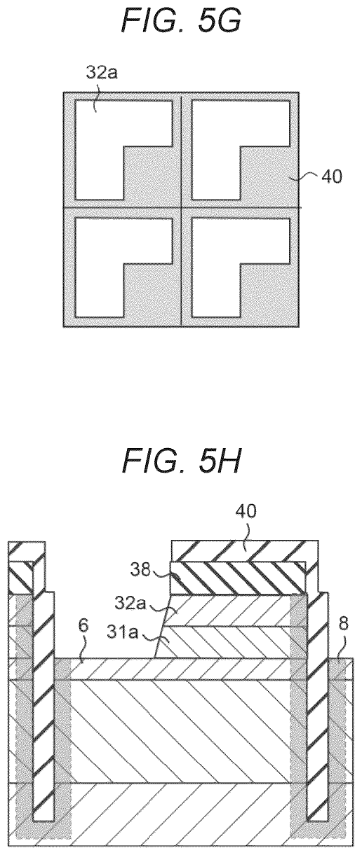

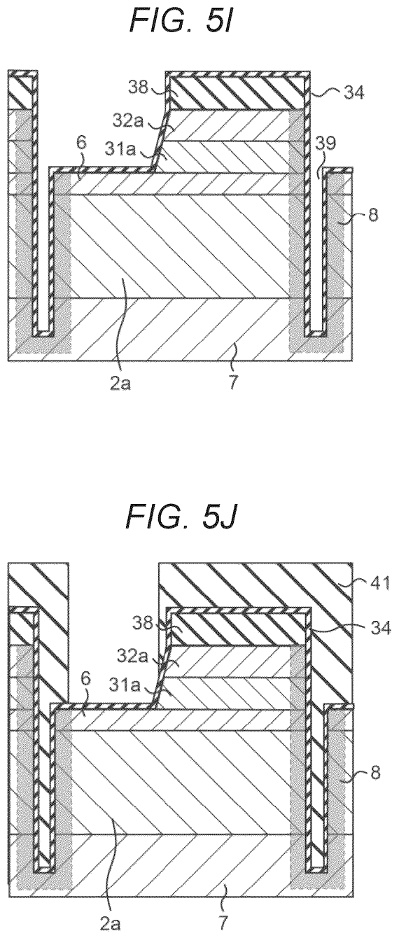

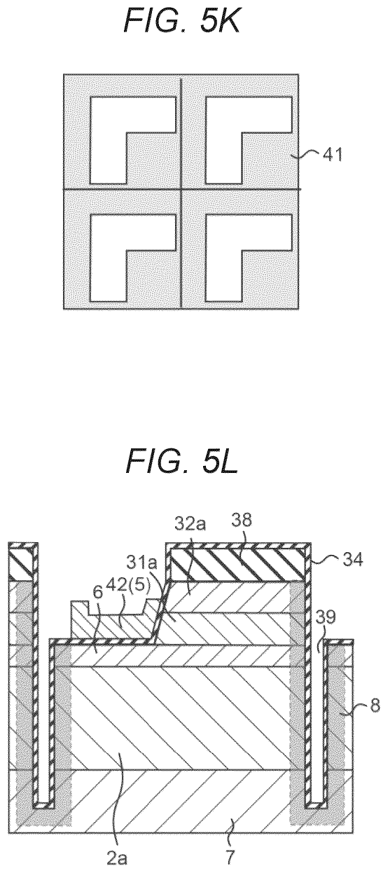

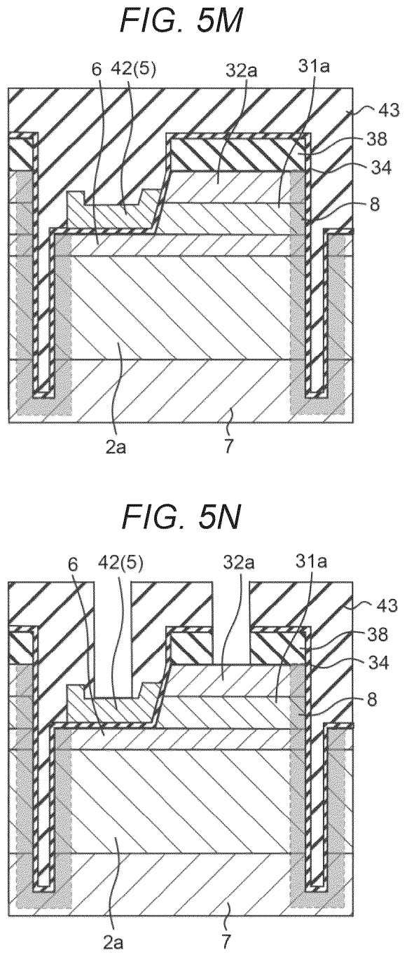

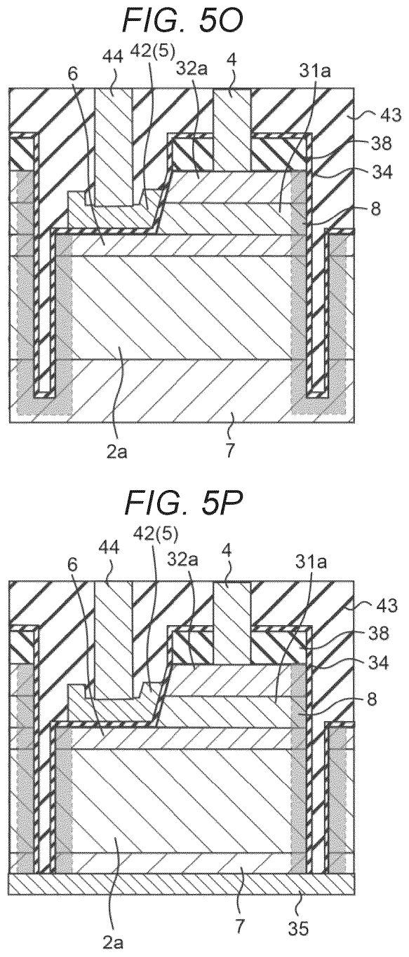

FIGS. 5A to 5P are cross-sectional views illustrating a process of manufacturing the photoelectric conversion element 1 according to the first embodiment. Hereinafter, a procedure for forming the photoelectric conversion element 1 by using a specific material will be described, but as described above, there is a plurality of candidates for the material that can constitute the photoelectric conversion element 1.

First, as illustrated in FIG. 5A, a stack structure 37, in which the p⁺-InP layer 7, a p-InGaAs layer 2a, the p⁺-InGaAs layer 6, a p-InP layer 31a, and an n⁺-InP layer 32a are stacked in this order, is formed by epitaxial growth. The thickness of the p-InGaAs layer 2a as the photoelectric conversion layer 2 is, for example, about 3 μm, and may range from about 100 nm to 100 μm.

In order to prevent leakage between the p-InGaAs layer 2a and the n⁺-InP layer 32a, the total thickness of the p⁺-InGaAs layer 6 and p-InP layer 31a is desirably about 500 μm, and may be a value ranging from 3 μm to 100 μm.

Next, as illustrated in FIG. 5B, an insulation film 38 for a hard mask is formed on the stack structure 37 formed in FIG. 5A. The insulation film 38 is an insulation material containing at least any of silicon (Si), nitrogen (N), aluminum (Al), hafnium (Hf), tantalum (Ta), titanium (Ti), oxygen (O), magnesium (Mg), scandium (Sc), zirconium (Zr), lanthanum (La), gadolinium (Gd), or yttrium (Y). Specifically, the insulation film 38 for a hard mask may be a silicon nitride (SiN) film, an aluminum oxide (Al₂O₃) film, a silicon oxide (SiO₂) film, a silicon oxynitride (SiON) film, an aluminum oxynitride (AlON) film, a silicon aluminum nitride (SiAlN) film, magnesium oxide (MgO), an aluminum silicon oxide (AlSiO) film, a hafnium oxide (HfO₂) film, an aluminum hafnium oxide (HfAlO) film, a tantalum oxide (Ta₂O₃) film, a titanium oxide (TiO₂) film, a scandium oxide (Sc₂O₃) film, a zirconium oxide (ZrO₂) film, a gadolinium oxide (Gd₂O₃) film, a lanthanum oxide (La₂O₃) film, or an yttrium oxide (Y₂O₃) film, and the insulation film 38 may be formed by stacking two or more of these films.

After the insulation film 38 for a hard mask is formed, a resist (not illustrated) is applied onto the insulation film 38, exposure and development processing are performed to process the resist to have a grid pattern for pixel separation, and then the insulation film 38 is selectively removed by dry etching or wet etching by using the processed resist as a mask. As a result, the insulation film 38 is defined in a grid pattern. Thereafter, the resist is removed by dry asking or wet etching.

Next, as illustrated in FIG. 5C, a part of the stack structure 37 formed in FIG. 5A is etched using the insulation film 38 patterned in FIG. 5B as a hard mask. Thus, a trench 39 is formed in the stack structure 37. In FIG. 5C, the bottom of the trench 39 is present inside the p⁺-InP layer 7, but the trench 39 may be formed so as to penetrate the p⁺-InP layer 7.

Next, as illustrated in FIG. 5D, a p-type impurity (for example, Zn) is diffused in the stack structure 37 from the sidewall of the trench 39 by a gas-phase diffusion process or a solid-phase diffusion process to form the diffusion layer 8. It is desirable to diffuse the p-type impurity by about 100 nm so as not to generate noise charge at the interface of the sidewall of the trench 39. Alternatively, the diffusion width of the p-type impurity may be in a range of 10 nm to 500 nm. The thermal diffusion temperature in performing the gas-phase diffusion process or the solid-phase diffusion process ranges from 300° C. to 800° C. The impurity to be diffused is a dopant having a polarity opposite to that of the read charge, and is a p-type dopant in a case where the read charge is an electron. The specific examples of the element to be diffused include zinc (Zn), magnesium (Mg), cadmium (Cd), beryllium (Be), silicon (Si), germanium (Ge), carbon (C), tin (Sn), lead (Pb), sulfur (S), tellurium (Te), phosphorus (P), boron (B), arsenic (As), indium (In), antimony (Sb), gallium (Ga), and aluminum (Al).

Next, as illustrated in FIG. 5E, an insulation film 40 is formed on the stack structure 37, the material of the insulation film 40 is embedded in the trench 39, and thus the trench 39 is filled with the insulation material. The insulation film 40 may not only fill the trench 39 but also cover the insulation film 38 for a hard mask.

Next, as illustrated in FIG. 5F, a resist (not illustrated) is applied onto the insulation film 40, exposure and development processing are performed to pattern the resist, and then the insulation film 40 is selectively removed by dry etching or wet etching by using the patterned resist as a mask. As a result, as illustrated in a plan view of FIG. 5G, the n⁺-InP layer 32a is partially exposed. Thereafter, the resist is removed by dry asking or wet etching.

Next, as illustrated in FIG. 5H, the n⁺-InP layer 32a and the p-InP layer 31a are removed by wet etching by using the patterned insulation film as a mask. At this time, the surface of the p⁺-InGaAs layer 6 is partially exposed and the p-InP layer 31a and the n⁺-InP layer 32a remain in a region where the p⁺-InGaAs layer 6 is not exposed.

Next, as illustrated in FIG. 5I, the insulation film 40 used for embedding the trench 39 is removed by wet etching or the like, and the entire surface is covered with the sealing insulation film 34. The sealing insulation film 34 is an insulation material containing at least any of silicon (Si), nitrogen (N), aluminum (Al), hafnium (Hf), tantalum (Ta), titanium (Ti), oxygen (O), magnesium (Mg), scandium (Sc), zirconium (Zr), lanthanum (La), gadolinium (Gd), or yttrium (Y). Specifically, the insulation film 34 may be a silicon nitride (SiN) film, an aluminum oxide (Al₂O₃) film, a silicon oxide (SiO₂) film, a silicon oxynitride (SiON) film, an aluminum oxynitride (AlON) film, a silicon aluminum nitride (SiAlN) film, magnesium oxide (MgO), an aluminum silicon oxide (AlSiO) film, a hafnium oxide (HfO₂) film, an aluminum hafnium oxide (HfAlO) film, a tantalum oxide (Ta₂O₃) film, a titanium oxide (TiO₂) film, a scandium oxide (Sc₂O₃) film, a zirconium oxide (ZrO₂) film, a gadolinium oxide (Gd₂O₃) film, a lanthanum oxide (La₂O₃) film, or an yttrium oxide (Y₂O₃) film, and the insulation film 34 may have a stack structure formed by stacking any of these films.

Next, as illustrated in FIG. 5J, a resist 41 is applied onto the insulation film 34, and exposure and development processing are performed to pattern the resist 41 to have the shape of the transfer gate 5 of a transfer transistor. The planar shape of the patterned resist 41 is, for example, an L shape as illustrated in FIG. 5K.

Next, as illustrated in FIG. 5L, a metal film 42 of copper (Cu) or the like is formed on the patterned resist 41. The metal film 42 is formed on the sealing insulation film at a place where the resist 41 is not applied. Thereafter, when the resist 41 is removed by dry asking or wet etching, the metal film on the resist 41 disappears (is lifted off) when the resist 41 is removed, and only the metal film at a place where the resist 41 is not applied remains. Thus, the transfer gate 5 is formed.

Next, as illustrated in FIG. 5M, an insulation film 43 is formed on the entire surface. The material of the insulation film 43 may be the same as or different from that of the above-described sealing insulation film 34.

Next, as illustrated in FIG. 5N, a resist (not illustrated) is applied onto the insulation film 43, exposure and development processing are performed, and the resist is patterned in accordance with a contact position for the FD electrode 4 and the contact position for the transfer gate 5. Next, the insulation film 43 is selectively removed by dry etching or wet etching by using the patterned resist as a mask. Thereafter, the resist mask is removed by dry asking or wet etching. Thus, the n⁺-InP layer 32a and the transfer gate 5 are partially exposed.

Next, as illustrated in FIG. 5O, a metal material is formed on the exposed portions of the n⁺-InP layer 32a and the transfer gate 5 to form a contact (FD electrode) 4 connected to the n⁺-InP layer 32a and a contact (electrode of the transfer gate 5) 44 connected to the transfer gate 5.

Next, as illustrated in FIG. 5P, the p⁺-InP layer 7 on the back surface (light irradiation surface) side is thinned. The thickness of the p⁺-InP layer 7 is desirably about 50 nm, and may range from 5 nm to 500 μm. As illustrated in FIG. 5P, an electrode 35 shared by a plurality of the pixels is formed on the thinned p⁺-InP layer 7. In a case where the electrode 35 covers the entire surface of the p⁺-InP layer 7, it is necessary to use a material for the transparent electrode 35 having a transmittance of 50% or more with respect to light having a wavelength of 1.6 μm.

As described above, in the photoelectric conversion element 1 and the imaging device according to the first embodiment, the pn junction is not provided inside the photoelectric conversion layer 2 including a compound semiconductor material, but the pn junction is provided in the mesa portion 3 formed on a part of the upper surface of the photoelectric conversion layer 2, and the band gap energy of the first semiconductor layer 31 and the band gap energy of the second semiconductor layer 32 in the mesa portion 3 is made larger than the band gap energy of the photoelectric conversion layer 2. Thus, generation of dark current at the pn junction can be suppressed. Furthermore, since the transfer gate 5 is disposed so as to face both the photoelectric conversion layer 2 and the mesa portion 3, the band offset at the interface between the photoelectric conversion layer 2 and the mesa portion 3 does not act as a transfer barrier for the read charge. Moreover, since the transfer gate 5 can control the transfer of the read charge, the reset potential in a state in which an optical signal is not input can be accurately detected, and the CDS operation can be performed. Furthermore, by providing, around the photoelectric conversion layer 2, the semiconductor layers 6 and 7 and the diffusion layer 8 containing the high-concentration impurity, it is possible to suppress liberation of noise charge on the surface of the photoelectric conversion layer 2 and to improve image quality.

Various modification examples are conceivable for the structure of the photoelectric conversion element 1 illustrated in FIG. 1 and FIG. 4. Hereinafter, typical modification example will be sequentially described as separate embodiments. Note that the photoelectric conversion element 1 for one pixel will be described below, but the photoelectric conversion element 1 of any of the embodiments can also constitute an imaging device including a plurality of the photoelectric conversion elements 1.

### Second Embodiment

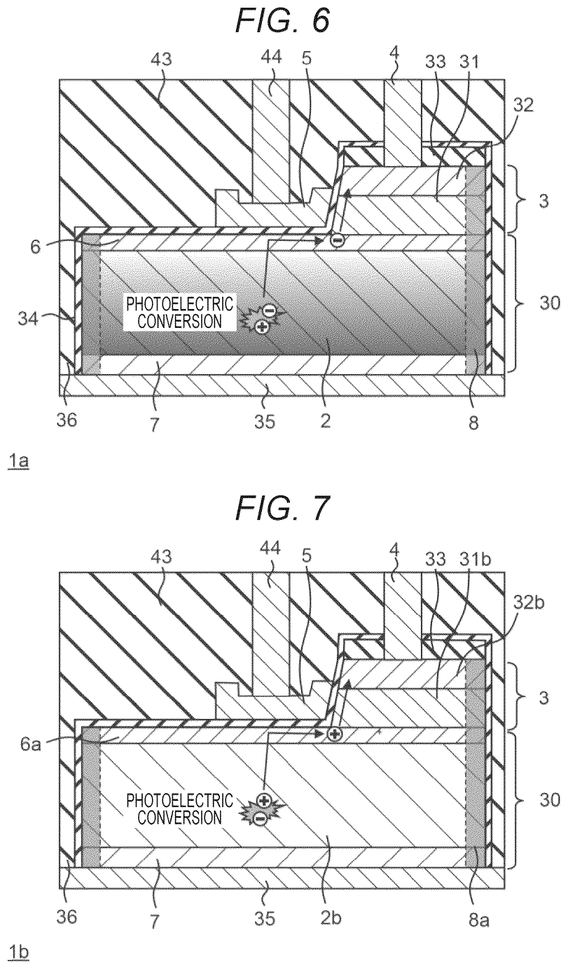

FIG. 6 is a cross-sectional view of a photoelectric conversion element 1a according to a second embodiment. In FIG. 6, components common to those in FIG. 1 are denoted by the same reference numerals, and differences will be mainly described below.

The photoelectric conversion element 1a of FIG. 6 has a gradient in the impurity concentration in the photoelectric conversion layer 2. More specifically, the photoelectric conversion layer 2 has a lower concentration of the impurity of the first conductivity type on the upper surface side closer to the mesa portion 3 and the transfer gate 5. The conductivity type of the impurity of the photoelectric conversion layer 2 is opposite to the conductivity type of the read charge. For example, in a case where the read charge is an electron, the impurity of the photoelectric conversion layer 2 is of a p-type, and in a case where the read charge is a hole, the impurity of the photoelectric conversion layer 2 is of an n-type.

As described above, by reducing the impurity concentration in accordance with the transfer direction of the photoelectric conversion layer 2, the read charge is easily transferred to the FD electrode 4 through the mesa portion 3, the afterimage can be suppressed, and response performance at the time of imaging is improved.

### Third Embodiment

FIG. 7 is a cross-sectional view of a photoelectric conversion element 1b according to a third embodiment. In FIG. 7, components common to those in FIG. 1 are denoted by the same reference numerals, and differences will be mainly described below.

The photoelectric conversion element 1b of FIG. 7 is obtained by reversing the conductivity type of the read charge from those of the photoelectric conversion elements 1 and 1a according to the first and second embodiments. That is, in the photoelectric conversion element 1b of FIG. 7, the read charge is set to a hole. In this case, a compound semiconductor material containing the n-type impurity is used for a photoelectric conversion layer 2b. The photoelectric conversion layer 2b is, for example, an n-InGaAs layer 2b. Alternatively, other materials can be selected.

On the upper surface of the photoelectric conversion layer 2b, for example, an n⁺-InGaAs layer 6a is epitaxially grown, and on the lower surface of the photoelectric conversion layer 2b, for example, an n⁺-InP layer 31b is epitaxially grown. On the sidewall of the photoelectric conversion layer 2b, a diffusion layer 8a having high-concentration n-type impurity (for example, germanium) is formed.

The mesa portion 3 includes a first semiconductor layer 31b and a second semiconductor layer 32b, the first semiconductor layer 31b is, for example, an n-InP layer 31b, and the second semiconductor layer 32 is, for example, a p⁺-InP layer 32b.

As described above, even when the read charge is the hole, similarly to the case of the electron, the generation of the dark current can be suppressed by providing the pn junction having large band gap energy in the mesa portion 3, and the hole can be transferred without being affected by the band offset and the reset potential can be accurately detected by providing the transfer gate 5. Therefore, the CDS operation can be performed.

An impurity concentration gradient may be provided in the photoelectric conversion layer 2b of FIG. 7 as in FIG. 6. In each of the following embodiments, the cross-sectional structure of the photoelectric conversion element 1b in a case where the read charge is an electron is illustrated, but the read charge may be a hole, and in a case where the read charge is the hole, the conductivity type of the impurity of each layer in each photoelectric conversion element 1a may be only required to reversed as in FIG. 7.

### Fourth Embodiment

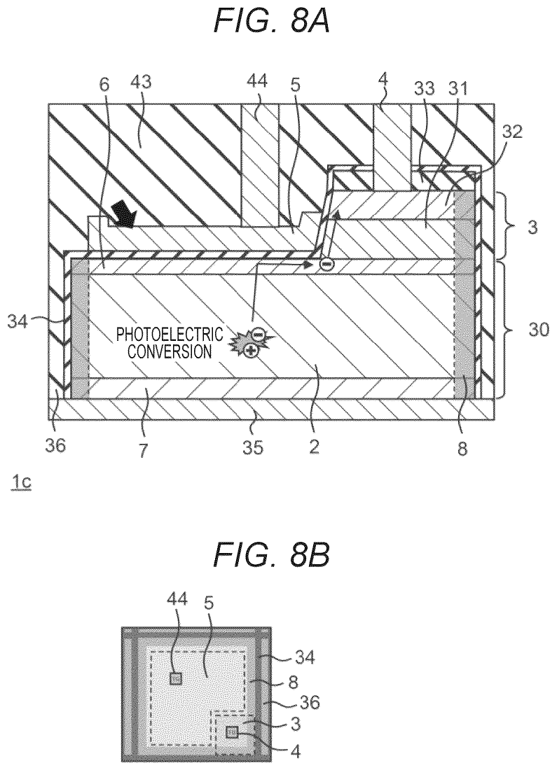

FIG. 8A is a cross-sectional view of a photoelectric conversion element 1c according to a fourth embodiment, and FIG. 8B is a plan view. The photoelectric conversion element 1c according to the fourth embodiment has a transfer gate 5 of which a structure is different from that of the transfer gate 5 of FIG. 1. As illustrated in FIG. 8A and FIG. 8B, the transfer gate 5 is disposed on the upper surface side of the photoelectric conversion layer 2 so as to face the entire surface of a region where the mesa portion 3 is not disposed. For example, as illustrated in the plan view of FIG. 8B, the mesa portion 3 is disposed at a corner portion in one pixel, and the transfer gate 5 is disposed in most of the portion other than the corner portion.

As described above, by increasing the area of the transfer gate 5, it is possible to guide the read charge existing at a place away from the mesa portion 3 in one pixel toward the mesa portion 3, and it is possible to further suppress the afterimage.

### Fifth Embodiment

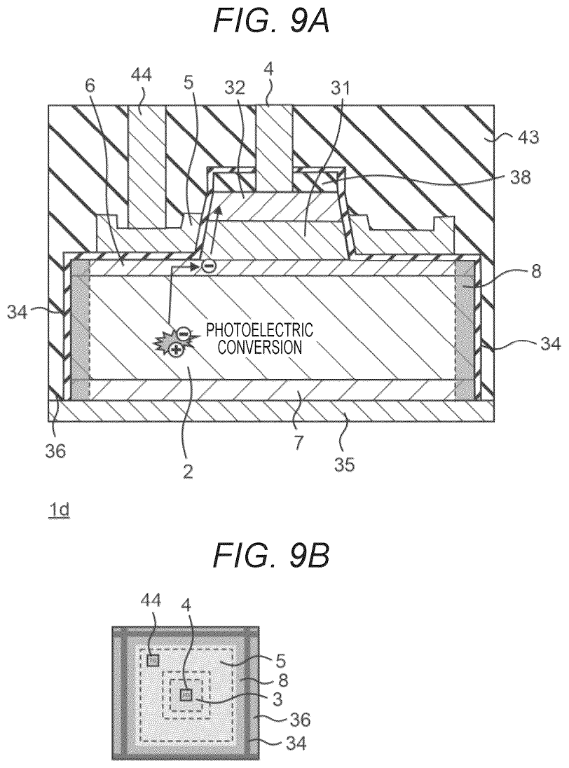

FIG. 9A is a cross-sectional view of a photoelectric conversion element 1d according to a fifth embodiment, and FIG. 9B is a plan view. In the photoelectric conversion element 1d according to the fifth embodiment, the mesa portion 3 and the FD electrode 4 are disposed near the center of the pixel. As illustrated in FIG. 9B, the transfer gate 5 is disposed so as to surround the mesa portion 3.

Therefore, a distance from a peripheral edge portion of the pixel to the FD electrode 4 can be made uniform, the collection efficiency of the read charge is improved, and the afterimage can be further suppressed.

### Sixth Embodiment

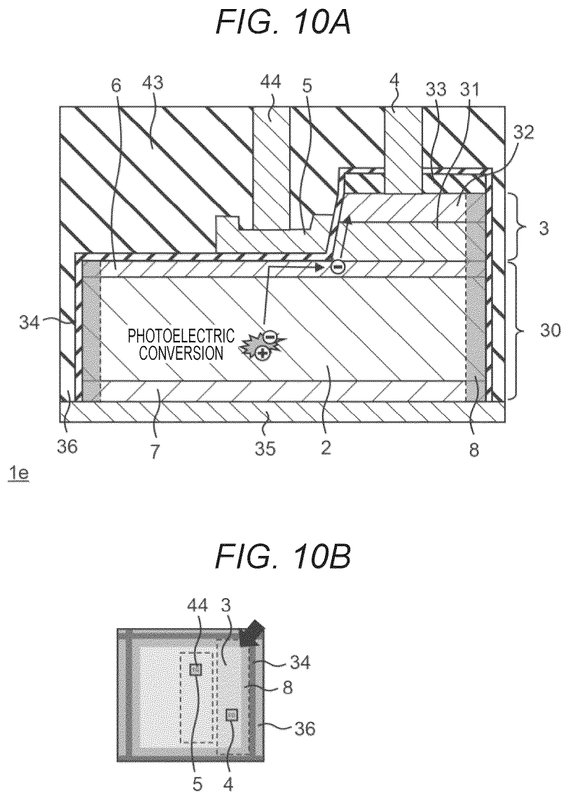

FIG. 10A is a cross-sectional view of a photoelectric conversion element be according to a sixth embodiment, and FIG. 10B is a plan view. In the photoelectric conversion element be according to the sixth embodiment, as illustrated in the plan view of FIG. 10B, the mesa portion 3 has a rectangular shape along one side of the pixel. The transfer gate 5 is disposed adjacent to the mesa portion 3 and has a rectangular shape like the mesa portion 3.

Therefore, since the area of the mesa portion 3 is larger than that of the photoelectric conversion element 1 in FIG. 1, the read charge easily moves toward the mesa portion 3, the collection efficiency of the read charge is improved, and the afterimage can be further suppressed.

### Seventh Embodiment

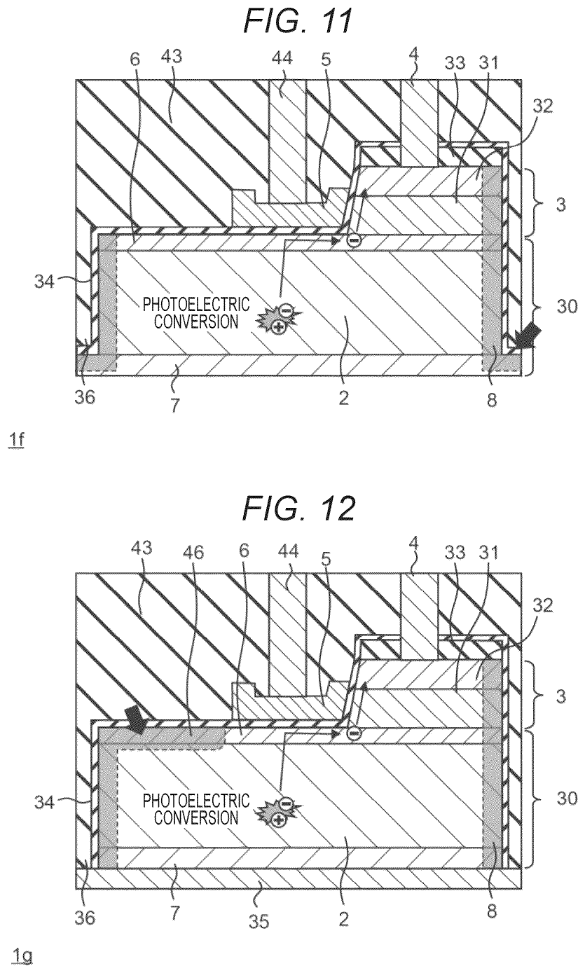

FIG. 11 is a cross-sectional view of a photoelectric conversion element 1f according to a seventh embodiment. A p⁺-InP layer 7 containing a high-concentration impurity is disposed on the back surface (light irradiation surface) side of the photoelectric conversion layer 2 in FIG. 1 and the like. The p⁺-InP layer 7 in FIG. 1 and the like is separated for each pixel by an insulation layer 36 disposed in a boundary region of the pixel. On the other hand, the p⁺-InP layer 7 of FIG. 11 is disposed across a plurality of the pixels without being separated for each pixel.

By disposing the p⁺-InP layer 7 across a plurality of the pixels without separating the p⁺-InP layer 7 for each pixel, the resistance of the p⁺-InP layer 7 can be reduced. Thus, when the p⁺-InP layer 7 has a high impurity concentration of 1×10¹⁸ cm⁻³ or more, the p⁺-InP layer 7 can be used as an electrode on the back surface side. In a case where the p⁺-InP layer 7 is used as an electrode, the transparent electrode 35 is unnecessary, and thus a manufacturing process and a member cost can be reduced and light loss when light is transmitted through the transparent electrode 35 does not occur. Therefore, the quantum efficiency can be improved.

### Eighth Embodiment

FIG. 12 is a cross-sectional view of a photoelectric conversion element 1g according to an eighth embodiment. The photoelectric conversion element 1g of FIG. 12 includes a diffusion layer (third diffusion layer) 46 including an impurity of the first conductivity type, which is disposed in a region where the mesa portion 3 is not disposed on the upper surface side of the photoelectric conversion layer 2. The diffusion layer 46 of FIG. 12 contains a high-concentration impurity having a polarity opposite to that of the read charge. The diffusion layer 46 of FIG. 12 is formed by, for example, gas-phase diffusion or solid-phase diffusion. Alternatively, the diffusion layer 46 may be formed by implantation of impurity ions and thermal diffusion.

The surface and interface of the photoelectric conversion layer 2 have many defects, and the noise charge is likely to be generated via an interface-defect level. Therefore, the generation of the noise charge can be suppressed by providing the diffusion layer 46, in which the impurity having a polarity opposite to that of the read charge is diffused at a high concentration, in the region where the noise charge is likely to be generated.

### Ninth Embodiment

FIG. 13 is a cross-sectional view of a photoelectric conversion element 1h according to a ninth embodiment. The photoelectric conversion element 1h of FIG. 13 includes a diffusion layer (fourth diffusion layer) 47 containing an impurity of the first conductivity type, which is disposed on at least a part of the sidewall of the mesa portion 3. The transfer gate 5 is disposed to face a part of the sidewall of the mesa portion 3. Thus, the diffusion layer 47 of FIG. 13 is disposed at a place where the transfer gate 5 is not disposed. In the example of FIG. 13, the sidewall of the mesa portion 3 on the pixel boundary side is processed to have a tapered shape, and the above-described diffusion layer 47 is disposed. The diffusion layer 47 is formed by, for example, gas-phase diffusion or solid-phase diffusion. Alternatively, the diffusion layer 46 may be formed by implantation of impurity ions and thermal diffusion.

By providing the diffusion layer 47 as illustrated in FIG. 13, it is possible to suppress generation of the noise charge on the sidewall portion of the mesa portion 3.

### Tenth Embodiment

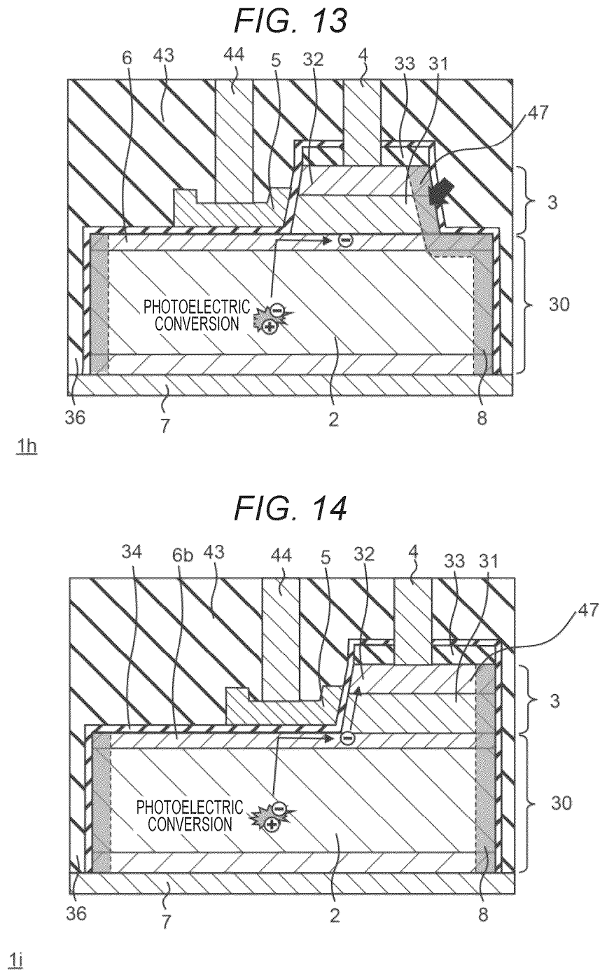

FIG. 14 is a cross-sectional view of a photoelectric conversion element 1i according to a tenth embodiment. In the photoelectric conversion element 1i of FIG. 14, an epitaxial layer 6b including a compound semiconductor material having band gap energy larger than that of the p⁺-InGaAs layer 6 of FIG. 1 is disposed on the upper surface of the photoelectric conversion layer 2. An example of such a material includes p⁺-InAlAs (indium aluminum arsenic).

The p⁺-InGaAs layer 6 of FIG. 1 functions as an etching-stop layer when the n⁺-InP layer 32a and the p-InP layer 31a are removed by etching in the process of FIG. 5H, but even in a case where the p⁺-InGaAs layer 6 is replaced with a p⁺-InAlAs layer 6b, the p⁺-InAlAs layer 6b can function as an etching-stop layer.

As described above, by providing a compound semiconductor layer (for example, p⁺-InAlAs layer) 6b having band gap energy larger than that of the photoelectric conversion layer 2 on the upper surface of the photoelectric conversion layer 2, more specifically, between the photoelectric conversion layer 2 and the mesa portion 3, the generation of noise charge near the interface between the p⁺-InAlAs layer 6b and the insulation film 34 is suppressed, and leakage between the p⁺-InAlAs layer 6b and an n⁺-InP layer 32 in the mesa portion 3 can be suppressed.

### Eleventh Embodiment

FIG. 15 is a cross-sectional view of a photoelectric conversion element 1j according to an eleventh embodiment. The photoelectric conversion element 1j of FIG. 15 includes an electrode (second electrode) 35a disposed on the upper surface side of the photoelectric conversion layer 2 instead of the transparent electrode 35 disposed on the back surface side in FIG. 1 and the like. Similarly to the photoelectric conversion element 1g of FIG. 12, the photoelectric conversion element 1j of FIG. 15 includes a diffusion layer (third diffusion layer) 46 including an impurity of the first conductivity type, which is disposed in a region where the mesa portion 3 is not disposed on the upper surface side of the photoelectric conversion layer 2. A diffusion layer 8 containing a high-concentration impurity is disposed on the sidewall of the photoelectric conversion element 1j, and the p⁺-InP layer 7 containing a high-concentration impurity is disposed on the back surface side of the photoelectric conversion element 1j. Therefore, the diffusion layer 46 disposed on the upper surface side of the photoelectric conversion layer 2 is electrically connected to the p⁺-InP layer 7 disposed on the back surface side of the photoelectric conversion layer 2 via the diffusion layer 8 disposed on the sidewall of the photoelectric conversion layer 2, and the transparent electrode 35 is unnecessary since an electrode 35a is connected to the diffusion layer 46 on the upper surface side.

A sealing insulation film 48 is disposed on the p⁺-InP layer 7. The insulation film 48 may be separated for each pixel or may be disposed across a plurality of the pixels.

As described above, in the photoelectric conversion element 1j of FIG. 15, instead of providing the transparent electrode 35 on the back surface (light irradiation surface) side of the photoelectric conversion layer 2, the electrode 35a electrically connected to the n⁺-InP layer 32a is provided on the upper surface side of the photoelectric conversion layer 2, and thus the process of forming the transparent electrode 35 is unnecessary. Furthermore, by removing the transparent electrode 35, light loss when light is transmitted through the transparent electrode 35 does not occur, and the quantum efficiency can be improved.

### Twelfth Embodiment

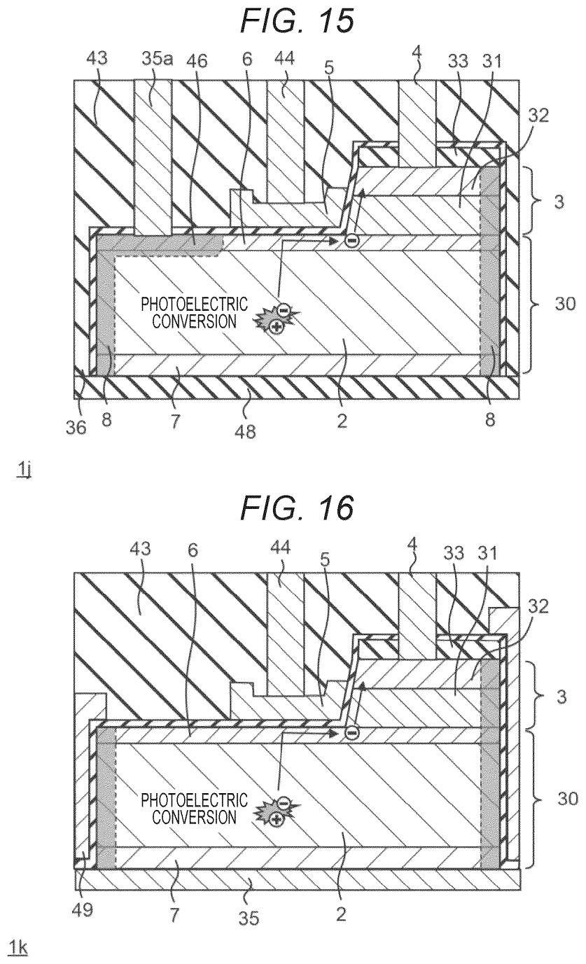

FIG. 16 is a cross-sectional view of a photoelectric conversion element 1k according to a twelfth embodiment. The photoelectric conversion element 1k of FIG. 16 includes a light-shielding metal layer 49 disposed in a boundary region of the pixel. The metal layer 49 is embedded in the trench of the stack structure 37 after the process of FIG. 5D. The light-shielding metal material is not particularly limited, and is, for example, tungsten (W).

By disposing the light-shielding metal layer 49 in the boundary region of the pixel, the leakage of light to adjacent pixels can be suppressed, and color mixing is reduced.

In FIG. 16, the metal layer 49 is disposed on the transparent electrode 35, but as illustrated in FIG. 15, the light-shielding metal layer 49 may be disposed in the pixel boundary region of the photoelectric conversion element 1k without the transparent electrode 35. FIG. 17 is a cross-sectional view illustrating an example in which the light-shielding metal layer 49 is disposed in the pixel boundary region of the photoelectric conversion element 1j in FIG. 15. In a photoelectric conversion element 1m of FIG. 17, the metal layer 49 extends to the back surface (light irradiation surface).

In the example of FIG. 17, a trench is formed from the back surface side of the photoelectric conversion layer 2, and the metal layer 49 is embedded in the trench. Therefore, the metal layer 49 is disposed up to the vicinity of the interface between the photoelectric conversion layer 2 and the mesa portion 3. However, by forming the trench up to the side wall of the mesa portion 3, the metal layer 49 can be disposed up to the sidewall portion of the mesa portion 3.

### Thirteenth Embodiment

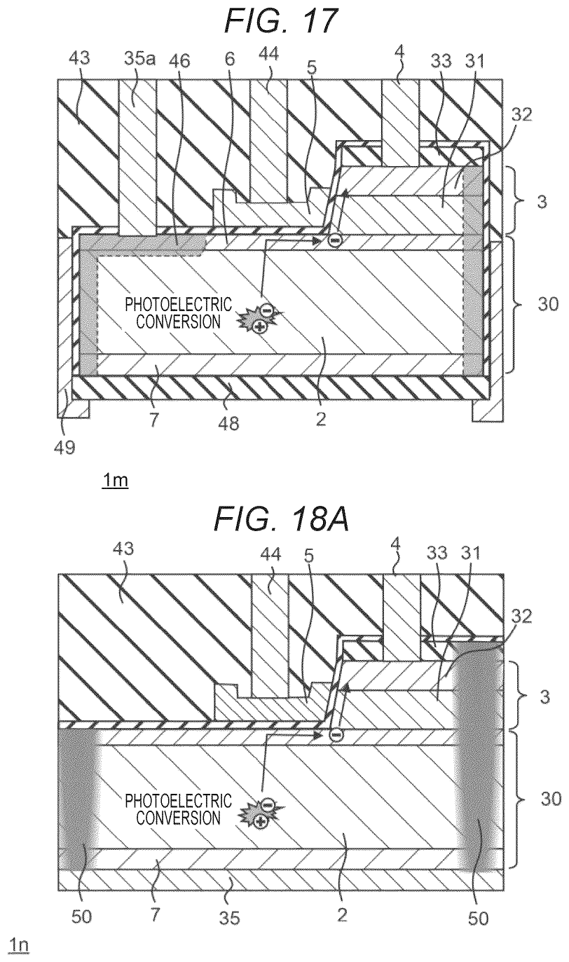

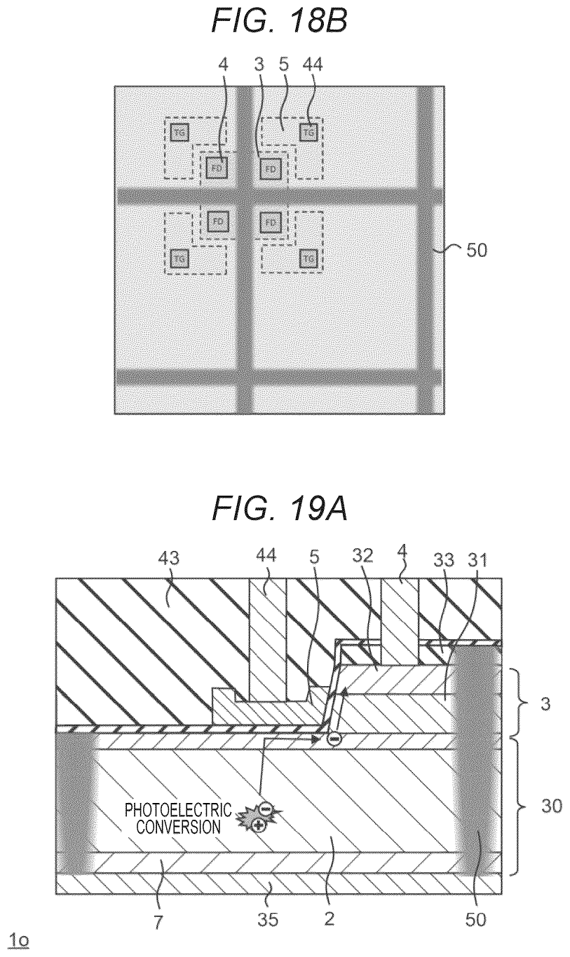

FIG. 18A is a cross-sectional view of a photoelectric conversion element 1n according to a thirteenth embodiment, and FIG. 18B is a plan view as viewed from above. The photoelectric conversion element 1n according to the thirteenth embodiment includes a diffusion layer (second diffusion layer) 50 for pixel separation, which is disposed in a boundary region of the pixel. The diffusion layer 50 according to the thirteenth embodiment is formed by implanting impurity ions from the upper surface side or the back surface side and thermally diffusing the impurity ions. The polarity of the impurity ions is opposite to the polarity of the read charge, and in a case where the read charge is an electron, p-type impurity ions are implanted. As illustrated in FIG. 18B, the diffusion layer 50 is formed by implanting impurity ions along the boundary of the pixel to have a grid shape. In the example of FIG. 18B, the mesa portion 3 (FD electrode 4) and the transfer gate 5 are disposed at a corner portion in the pixel.

As described above, in a case where the diffusion layer 50 for pixel separation is formed by implantation of the impurity ions, a process for pixel separation (FIGS. 5B to 5F) becomes unnecessary, and the manufacturing process can be simplified.

In the present embodiment, as illustrated in FIGS. 8 to 10, arrangement positions of the FD electrode 4 and the transfer gate 5 in the pixel are arbitrary, and various modification examples are conceivable. In any of the modification examples, the diffusion layer 50 for pixel separation is disposed along the boundary of the pixels.

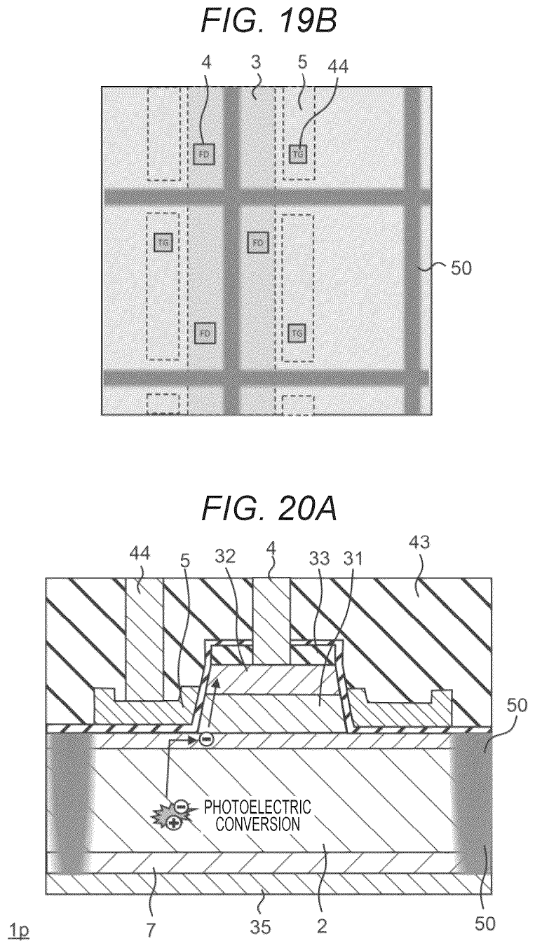

FIG. 19A is a cross-sectional view of a photoelectric conversion element 10 according to a first modification example of FIG. 18A, and FIG. 19B is a plan view of the first modification example. In the photoelectric conversion element 10 in FIG. 19A and FIG. 19B, as in FIG. 10, the mesa portion 3 is disposed along one side in the pixel, and the transfer gate 5 is disposed along the long side of the mesa portion 3.

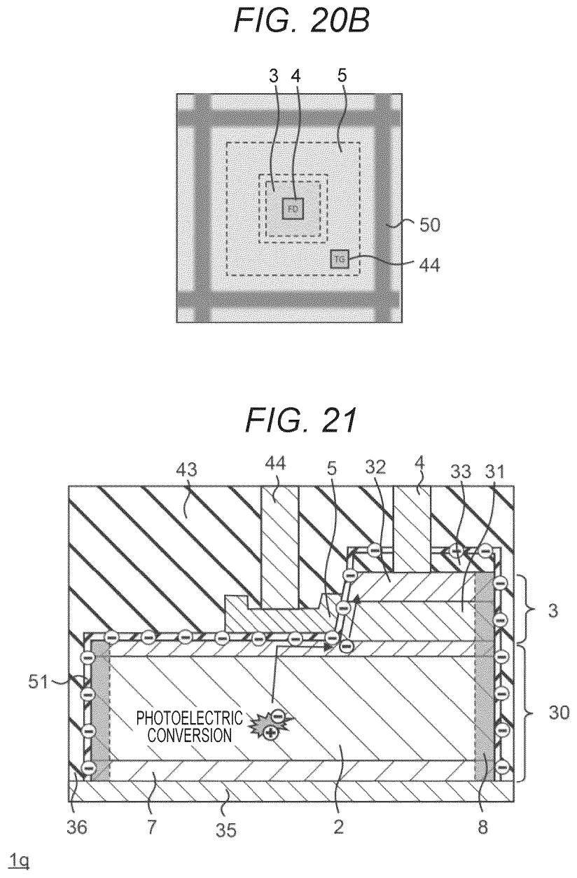

FIG. 20A is a cross-sectional view of a photoelectric conversion element 1p according to a second modification example of FIG. 18A, and FIG. 20B is a plan view of the second modification example. In the photoelectric conversion element 1p in FIG. 20A and FIG. 20B, as in FIG. 9, the mesa portion 3 and the FD electrode 4 are disposed on a center portion in the pixel, and the transfer gate 5 is disposed so as to surround the periphery of the mesa portion 3.

As described above, in the photoelectric conversion element 1p according to the thirteenth embodiment, since the diffusion layer 50 for pixel separation is formed by implantation of impurity ions, a process of forming a trench for pixel separation and forming a diffusion layer containing a high-concentration impurity on the sidewall of the trench and a process of embedding an insulation material in the trench are unnecessary, and thus the manufacturing process can be simplified.

### Fourteenth Embodiment

FIG. 21 is a cross-sectional view of a photoelectric conversion element 1q according to a fourteenth embodiment. The photoelectric conversion element 1q of FIG. 21 includes an insulation film 51 having fixed charge which is disposed so as to cover at least a part of the periphery of the photoelectric conversion layer 2 and mesa portion 3. The fixed charge is charge having the same polarity as the read charge. Some materials of the insulation film 51 include fixed charge having a predetermined polarity depending on the material. Therefore, by covering the periphery of the photoelectric conversion layer 2 and mesa portion 3 with the insulation film 51 containing charge having the same polarity as the read charge, charge having a polarity opposite to that of the fixed charge in the insulation film 51 is induced at the interface between the insulation film 51 and the photoelectric conversion layer 2 and the interface between the insulation film 51 and the mesa portion 3, and the generation of noise charge having the same polarity as that of the read charge at the interface can be suppressed.

### Fifteenth Embodiment

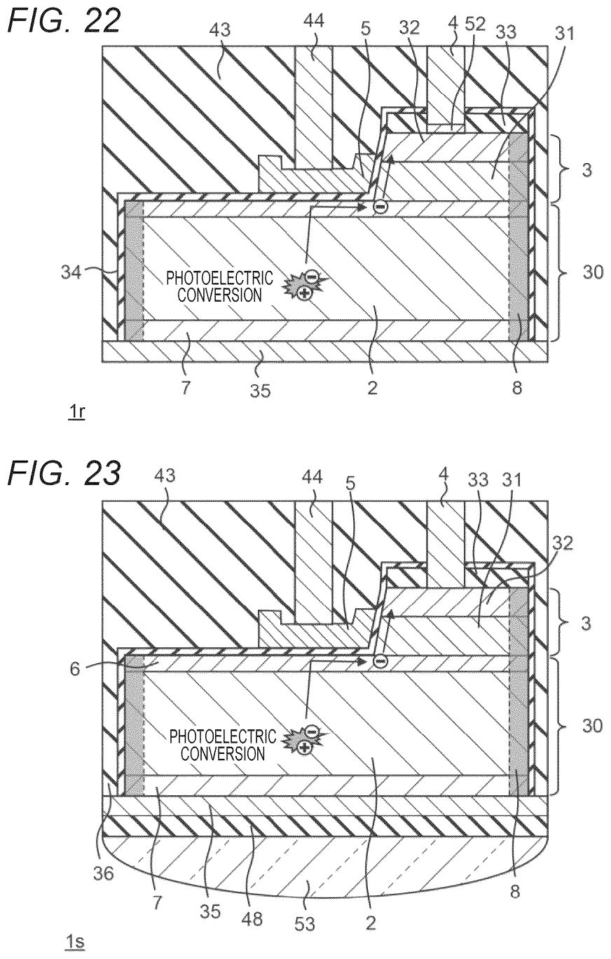

FIG. 22 is a cross-sectional view of a photoelectric conversion element 1r according to a fifteenth embodiment. The photoelectric conversion element 1r of FIG. 22 includes a third semiconductor layer 52 of the second conductivity type, which is disposed between the FD electrode 4 and the second semiconductor layer 32 in the mesa portion 3. The third semiconductor layer 52 has band gap energy smaller than the band gap energy of the first semiconductor layer 31 and the band gap energy of the second semiconductor layer 32 in the mesa portion 3. The third semiconductor layer 52 includes a compound semiconductor material containing an impurity having the same polarity as that of the read charge, and for example, in a case where the read charge is an electron, an n⁺-InGaAs layer or the like is used.

As described above, by sandwiching the third semiconductor layer 52 including a material having band gap energy smaller than that of InP between the FD electrode 4 and the second semiconductor layer 32 (n⁺-InP layer 32a), contact resistance can be reduced. When the contact resistance is large, it causes a decrease in response speed, a decrease in sensitivity, and deterioration of the afterimage. Therefore, by bringing the third semiconductor layer 52 having a small contact resistance into contact with the FD electrode 4, the response speed and the sensitivity can be improved, and the afterimage can be suppressed.

### Sixteenth Embodiment

FIG. 23 is a cross-sectional view of a photoelectric conversion element is according to a sixteenth embodiment. In the photoelectric conversion element is in FIG. 23, an on-chip lens 53 which is an optical member for condensing light on the photoelectric conversion layer 2 is disposed on the back surface (light irradiation surface) side of the photoelectric conversion layer 2. More specifically, the on-chip lens 53 is disposed so as to be in contact with a sealing insulation film. Furthermore, a color filter may be disposed between the sealing insulation film and the on-chip lens 53.

By providing the on-chip lens 53, it is possible to reduce light incident on the vicinity of the boundary of the pixel, which do not contribute to photoelectric conversion, and to improve the quantum efficiency.

### Seventeenth Embodiment

As described above, when a diffusion layer 8 is formed by diffusing Zn in the trench sidewall portion of the pixel boundary region, there is a possibility that a part of Zn enters the first semiconductor layer 31 and the second semiconductor layer 32 in the mesa portion 3 to form a strong electric field region between the first semiconductor layer 31 and the second semiconductor layer 32. It is also possible to make a structure in which such a strong electric field region is not formed.

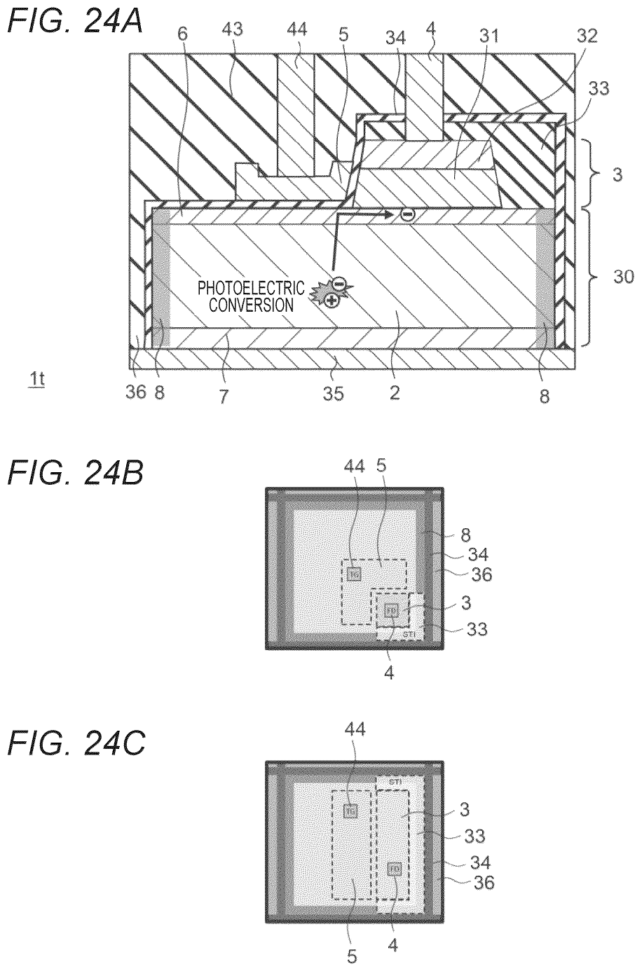

FIG. 24A is a cross-sectional view of a photoelectric conversion element it according to a seventeenth embodiment, and FIG. 24B and FIG. 24C are plan views. As illustrated in FIG. 24A, in the photoelectric conversion element it, the side surface and upper surface of the first semiconductor layer 31 and second semiconductor layer 32 in the mesa portion 3 on the diffusion layer 8 side are covered with the insulation film 33. For the insulation film 33, for example, an insulation material such as silicon nitride (SiN) can be used. By providing the insulation film 33, Zn is not diffused into the first semiconductor layer 31 and the second semiconductor layer 32, and a strong electric field region is not formed between the first semiconductor layer 31 and the second semiconductor layer 32.

The mesa portion 3 and the insulation film 33 may be disposed at a corner portion of the pixel as illustrated in FIG. 24B, or may be disposed along one side of the pixel as illustrated in FIG. 24C.

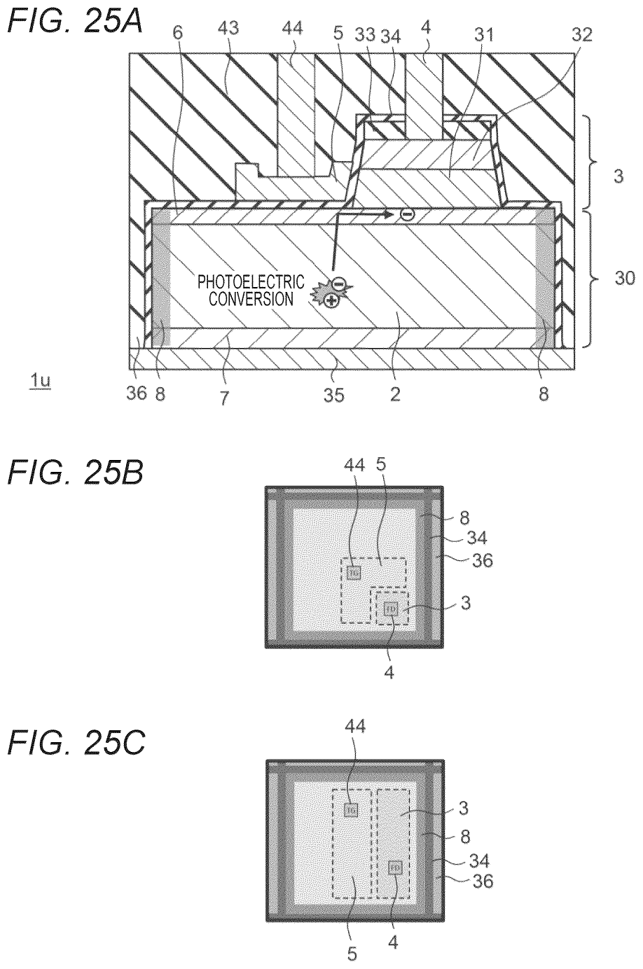

FIG. 25A is a cross-sectional view of a photoelectric conversion element 1u according to a modification example of FIG. 24A, and FIG. 25B and FIG. 25C are plan views. As illustrated in FIG. 25A, after a diffusion layer 8 is formed by diffusing Zn into the trench sidewall portion of the pixel boundary portion, the sidewall portion of the first semiconductor layer 31 and second semiconductor layer 32 in the mesa portion 3 on the diffusion layer 8 side is removed by etching or the like, such that Zn can be prevented from diffusing into the first semiconductor layer 31 and the second semiconductor layer 32.

As described above, in the photoelectric conversion elements it and 1u described above, Zn in the diffusion layer 8 is not diffused into the first semiconductor layer 31 and the second semiconductor layer 32 in the mesa portion 3, and a strong electric field region is not formed between the first semiconductor layer 31 and the second semiconductor layer 32.

### Eighteenth Embodiment

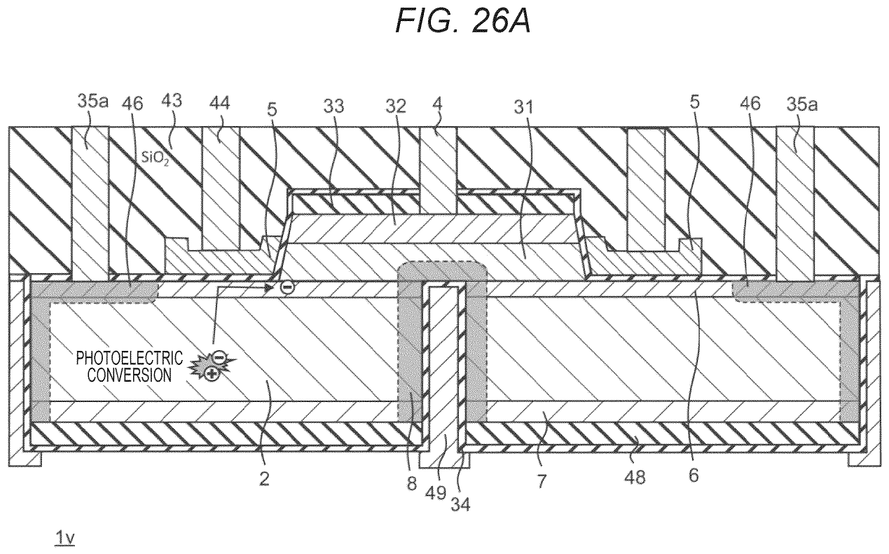

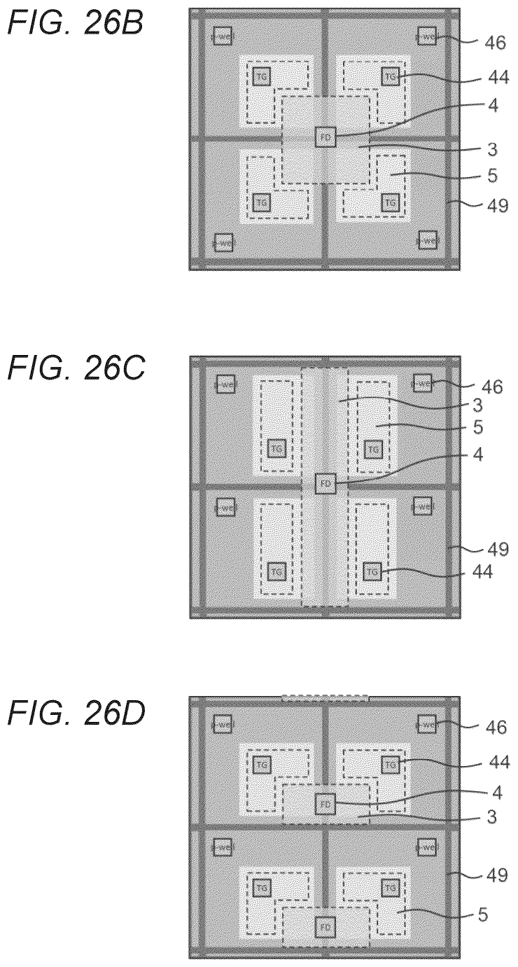

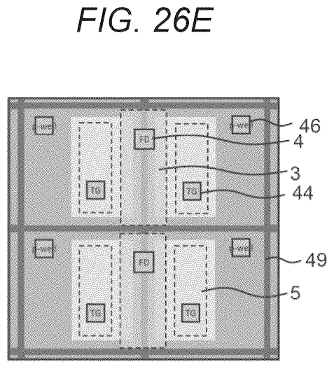

FIG. 26A is a cross-sectional view of a photoelectric conversion element 1v according to an eighteenth embodiment, and FIG. 26B is a plan view. In the photoelectric conversion element 1v according to the eighteenth embodiment, the mesa portion 3 and the transfer gate 5 are shared by a plurality of pixels (for example, two pixels or four pixels). FIG. 26A and FIG. 26B illustrate an example in which four pixels share the mesa portion 3 and the transfer gate 5. As illustrated in the plan view of FIG. 26B, the mesa portion 3 and the FD electrode 4 are provided at the center of a 2×2 pixel, and the transfer gates 5 are disposed around the mesa portion 3 and the FD electrode 4.

As illustrated in FIG. 26A and FIG. 26B, the FD electrode 4 is disposed in the boundary region of the pixel, and a light-shielding metal layer 49 for pixel separation is disposed below the FD electrode 4. A p⁺-diffusion layer 8 containing a high-concentration impurity is formed around the metal layer 49 via the insulation film 34. In the metal layer 49, for example, a trench is formed from the back surface side along the boundary region of the pixel, the p⁺-diffusion layer 8 is formed on the sidewall portion of the trench by gas-phase diffusion or solid-phase diffusion, and then the metal layer 49 is formed by embedding a metal material in the trench.

By providing the p⁺-diffusion layer 8 around the metal layer 49 disposed in the boundary region of the pixel, it is possible to suppress the generation of noise charge at the interface between the photoelectric conversion layer 2 and the metal layer 49.

FIG. 26C is a plan view of a first modification example in FIG. 26B. In FIG. 26C, the mesa portion 3 having a rectangular planar shape is disposed along a pixel boundary extending in a Y direction from an intermediate position of the 2×2 pixel in an X direction, and the transfer gate 5 having a rectangular planar shape is disposed along the mesa portion 3. The FD electrode 4 is disposed near the center of the four pixels.

FIG. 26D is a plan view of a second modification example in FIG. 26B. In FIG. 26D, four mesa portions 3 are disposed close to each other at a central corner portion of the pixel boundary extending in the X direction of the 2×2 pixel, and the transfer gates 5 are disposed around the mesa portions 3. In FIG. 26D, the FD electrode 4 is shared by two pixels adjacent in the X direction.

FIG. 26E is a plan view of a third modification example in FIG. 26B. In FIG. 26E, the arrangement positions of the mesa portion 3 and transfer gate 5 are similar to those in FIG. 26C, but the position of the FD electrode 4 is different. The FD electrode 4 in FIG. 26E is shared by two pixels adjacent in the X direction, and these two FD electrodes 4 are disposed at positions shifted from the center of the four pixels in the Y direction.

In the photoelectric conversion element 1v according to the eighteenth embodiment, the FD electrode 4 and the mesa portion 3 are shared by a plurality of the pixels, such that that the pixel size can be reduced, and a read transistor (not illustrated) connected to the FD electrode 4 only needs to be provided for each of a plurality of the pixels, such that the circuit scale of the read circuit can also be reduced.

### Nineteenth Embodiment

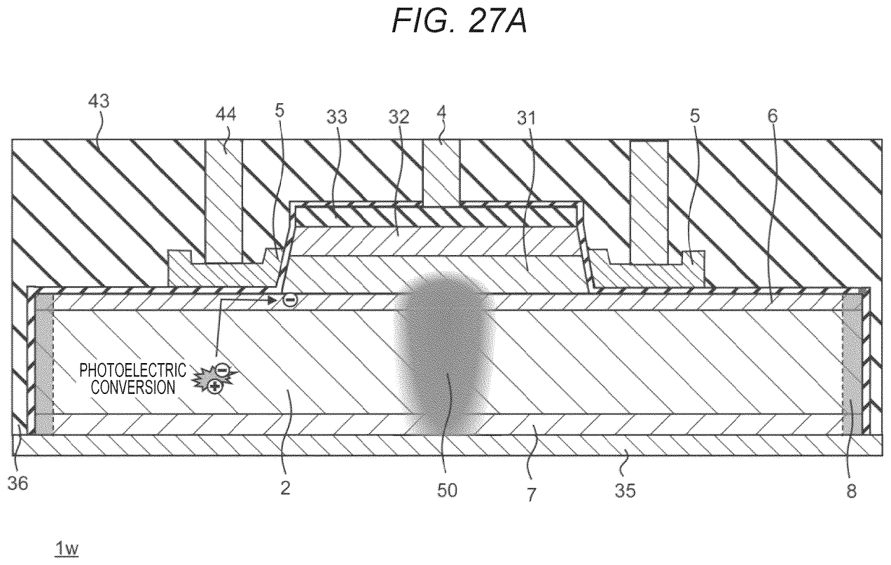

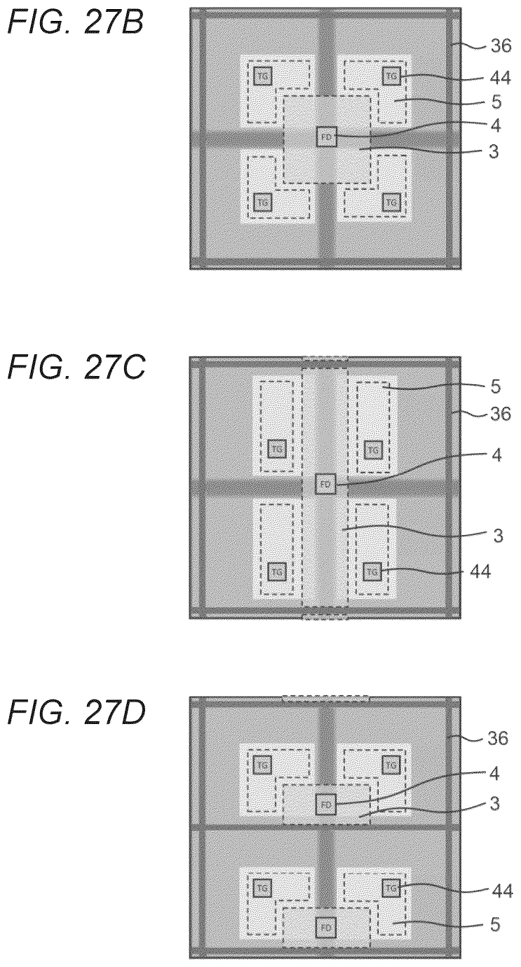

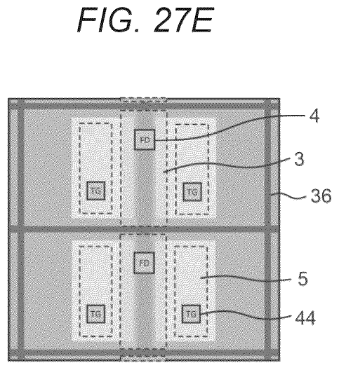

FIG. 27A is a cross-sectional view of a photoelectric conversion element 1w according to a nineteenth embodiment, and FIG. 27B is a plan view. The photoelectric conversion element 1w according to the nineteenth embodiment is the same as the photoelectric conversion element 1v according to the eighteenth embodiment in that the mesa portion 3 and the transfer gate 5 are shared by a plurality of pixels, but is different in that the diffusion layer 50 for pixel separation is provided in the pixel boundary region instead of the insulation layer 36 or the metal layer 49. As described in the thirteenth embodiment (FIG. 18A and the like), the diffusion layer 50 is formed by implanting impurity ions having a polarity opposite to that of the read charge and thermally diffusing the impurity ions.

For example, the planar structure of the photoelectric conversion element 1w according to the nineteenth embodiment is similar to those in FIGS. 26B to 26D and specifically, a case where the FD electrode 4 is shared by four pixels as illustrated in FIGS. 27B to 27C and a case where the FD electrode 4 is shared by two pixels as illustrated in FIGS. 27D to 27E are considered.

In the photoelectric conversion element 1w according to the nineteenth embodiment, since a series of manufacturing processes of forming a trench in a pixel boundary region, forming the diffusion layer 50 by gas-phase diffusion or solid-phase diffusion, and then filling the trench with an insulation layer is unnecessary, manufacturing can be easily performed as compared with the photoelectric conversion element 1v according to the eighteenth embodiment.

### Twentieth Embodiment

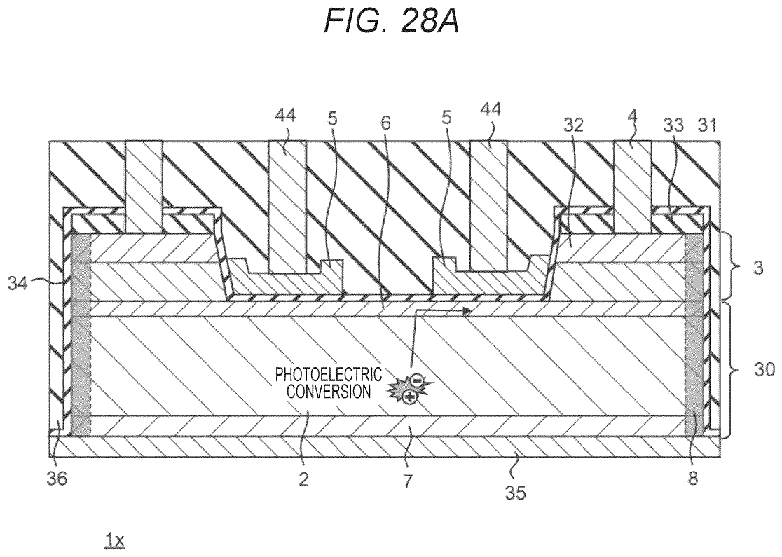

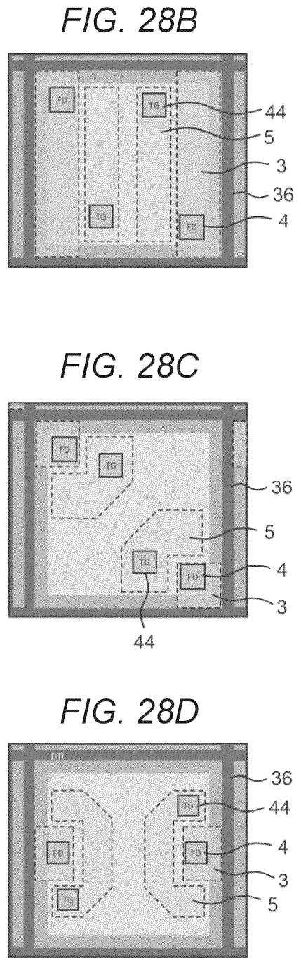

FIG. 28A is a cross-sectional view of a photoelectric conversion element 1x according to a twentieth embodiment, and FIG. 28B is a plan view. The photoelectric conversion element 1x according to the twentieth embodiment has a structure that can be used as an indirect time of flight (iToF) sensor.

The photoelectric conversion element 1x according to the twentieth embodiment includes a plurality of pixels (for example, two pixels or four pixels) disposed adjacent to each other without a pixel boundary. In the photoelectric conversion layer 2, a plurality of pixels is integrally connected, and the read charge can also move to a region of the adjacent pixel. The mesa portion 3 and the transfer gate 5 are provided corresponding to each of a plurality of the pixels. For example, in a case where the photoelectric conversion element 1x includes two pixels, voltages are alternately applied to two transfer gates 5, and two transfer transistors are alternately turned on. When an object to be subjected to distance measurement is irradiated with pulsed light and light reflected from the object is received by the photoelectric conversion element 1x according to the twentieth embodiment, two transfer transistors are alternately turned on such that that the read charge is alternately transferred to two FD electrodes 4 connected to two mesa portions 3. The phase difference can be detected from a difference between charge amounts of the read charge transferred to two FD electrodes 4, and the distance can be measured.

As illustrated in the plan view of FIG. 28B, the mesa portion 3 having a rectangular planar shape and the transfer gate 5 are disposed along two opposite sides of the pixel. Various modification examples are conceivable for the planar shapes of the mesa portion 3 and the transfer gate 5. In a first modification example illustrated in FIG. 28C, the mesa portions 3 are disposed at two diagonal corners in the pixel, and the transfer gates 5 are disposed around the mesa portions 3. In a second modification example illustrated in FIG. 28D, the mesa portion 3 is disposed at the center portion of two opposite sides of the pixel, and the transfer gate 5 is disposed so as to surround the mesa portion 3.

### Twenty-First Embodiment

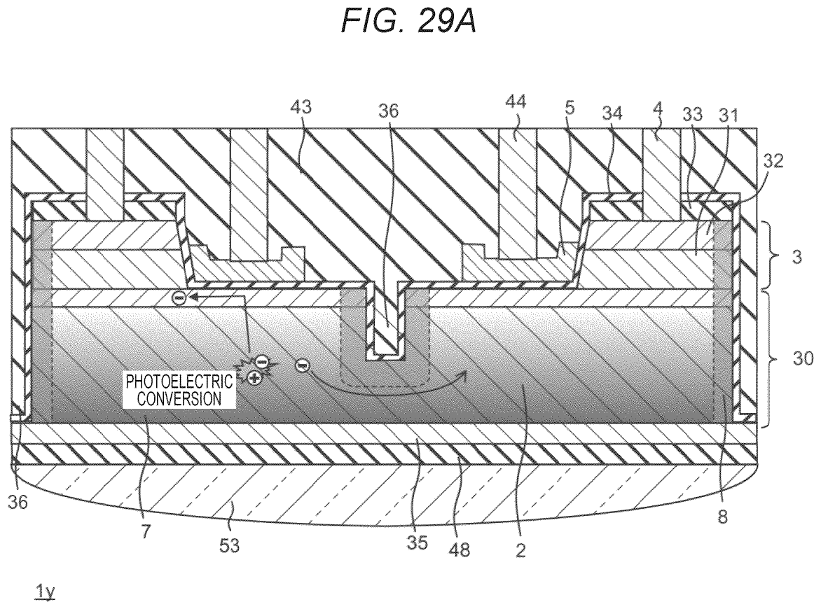

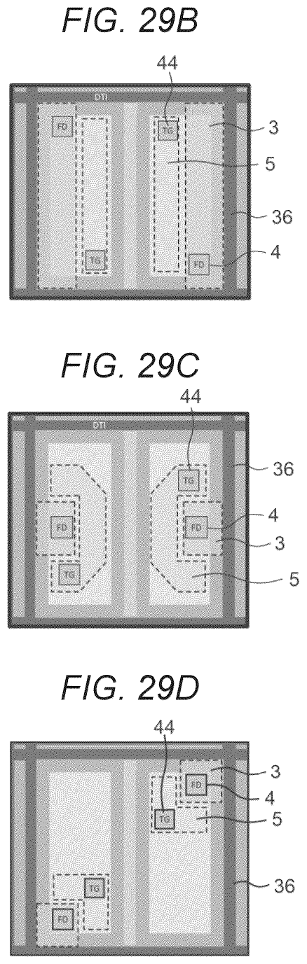

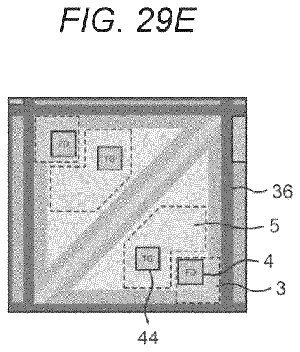

FIG. 29A is a cross-sectional view of a photoelectric conversion element 1y according to a twenty-first embodiment, and FIG. 29B is a plan view. As in FIG. 28A, the photoelectric conversion element 1y according to the twenty-first embodiment includes a plurality of pixels (for example, two pixels or four pixels) disposed adjacent to each other without a pixel boundary.

A trench having a depth not completely penetrating the photoelectric conversion layer 2 is formed in the boundary region of the pixel, and the insulation layer 36 is embedded in the trench. Furthermore, the p⁺-diffusion layer 8 containing a high-concentration impurity is disposed on the sidewall of the insulation layer 36. For example, the photoelectric conversion layer 2 including p-InGaAs may have an impurity concentration gradient from the back surface side toward the upper surface side.

A plurality of the pixels is disposed adjacent to each other in a state in which the photoelectric conversion layer 2 is not completely separated, and the read charge is movable into the adjacent pixel. More specifically, an overflow path through which the read charge overflowing in each pixel is moved to an adjacent pixel is provided.

Each pixel includes a mesa portion 3 and a transfer gate 5, and detects the read charge for each pixel. The difference in the read charge between the pixels is a phase difference, and the phase difference can be used, for example, for focus adjustment of an optical system.

As described above, the photoelectric conversion element 1y according to the twenty-first embodiment can be used as a focus adjustment sensor.

As illustrated in the plan view of FIG. 29B, the mesa portion 3 and the transfer gate 5, which have a rectangular planar shape, are disposed along two opposite sides of the pixel. Various modification examples are conceivable for the arrangement and shape of the mesa portion 3 and the transfer gate 5. For example, in the first modification example illustrated in FIG. 29C, the mesa portion 3 is disposed at the center portion of two opposite sides of the pixel, and the transfer gate 5 is disposed around the mesa portion 3. In a second modification example illustrated in FIG. 29D, the mesa portions 3 are disposed at diagonal corners in the pixel, and the transfer gates 5 are disposed around the mesa portions 3. A third modification example illustrated in FIG. 29E is different from FIG. 29D in that a boundary direction of the pixel is provided in a diagonal direction of the pixel.

### Twenty-Second Embodiment

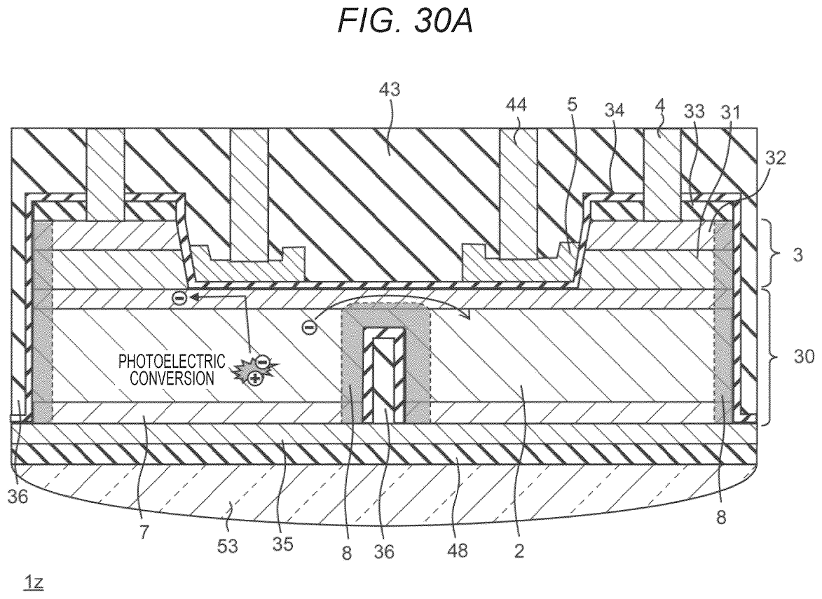

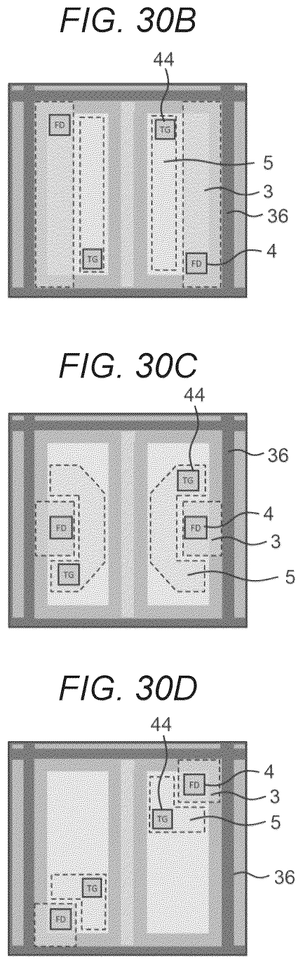

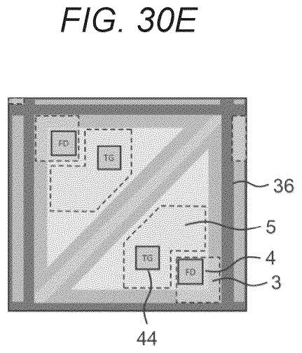

FIG. 30A is a cross-sectional view of a photoelectric conversion element 1z according to a twenty-second embodiment, and FIG. 30B is a plan view. Similarly to the photoelectric conversion element 1y according to the twenty-first embodiment, the photoelectric conversion element 1z according to the twenty-second embodiment can be used as a phase difference detection sensor. In the photoelectric conversion element 1z of FIG. 30A, the position of the insulation layer 36 disposed in the pixel boundary region is different from that in FIG. 29A. The insulation layer 36 in FIG. 30A is embedded inside a trench formed from the back surface side and having a depth not completely penetrating the photoelectric conversion layer 2. The read charge overflowing in the photoelectric conversion layer 2 of each pixel flows to the adjacent pixel through above the insulation layer 36.

As described above, in the photoelectric conversion element 1z of FIG. 30A, the overflow path of the read charge is provided above the insulation layer 36, and the photoelectric conversion element 1z is different from the photoelectric conversion element 1y in FIG. 29A in which the overflow path is provided below the insulation layer 36.

FIGS. 30B to 30E illustrate various planar shapes of the photoelectric conversion element 1z according to the twenty-second embodiment, are substantially the same as FIGS. 29B to 29E, and thus detailed description thereof will be omitted.

### Twenty-Third Embodiment

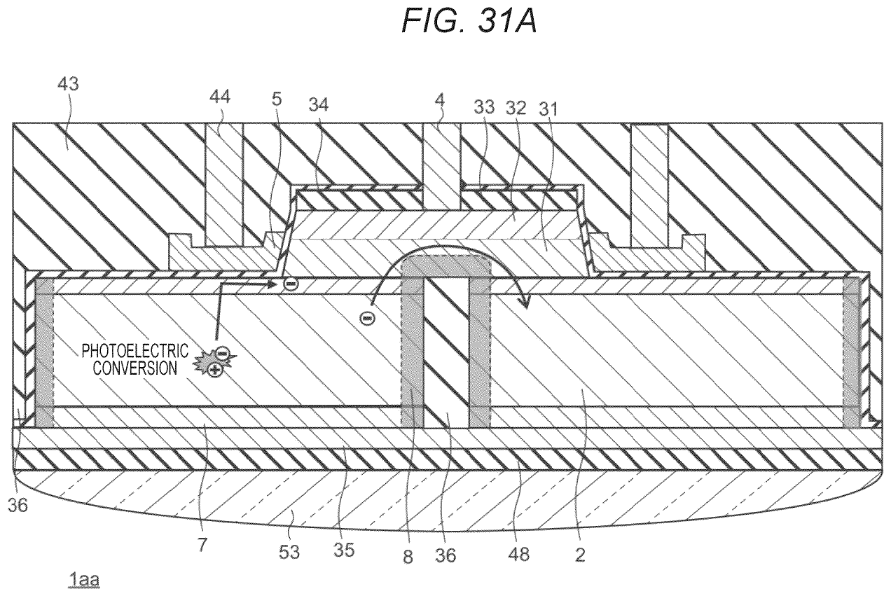

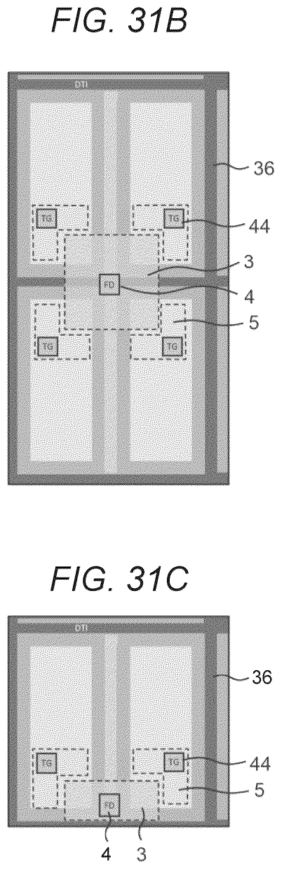

FIG. 31A is a cross-sectional view of a photoelectric conversion element 1aa according to a twenty-third embodiment, and FIG. 31B is a plan view. Similarly to the photoelectric conversion element 1 according to the twenty-first embodiment, the photoelectric conversion element 1aa according to the twenty-third embodiment can be used as a phase difference detection sensor.

In the photoelectric conversion element 1aa of FIG. 31A, the mesa portion 3 and the FD electrode 4 are shared by a plurality of adjacent pixels (for example, two pixels or four pixels). The mesa portion 3 and the FD electrode 4 are disposed in a pixel boundary region. Furthermore, in the photoelectric conversion element 1aa of FIG. 31A, the position of the insulation layer disposed in the pixel boundary region is different from those in FIG. 29A and FIG. 30A.

The insulation layer 36 in FIG. 31A is embedded inside a trench formed from the back surface side and having a depth penetrating the photoelectric conversion layer 2. The read charge overflowing in the photoelectric conversion layer 2 of each pixel flows to the adjacent pixel via the p-InP layer 31a in the mesa portion 3.

As described above, in the photoelectric conversion element 1aa of FIG. 31A, the overflow path of the read charge is provided so as to pass through from the photoelectric conversion layer 2 to the mesa portion 3, and the photoelectric conversion element 1aa is different from those in FIG. 29A and FIG. 30B in which the overflow path is provided inside the photoelectric conversion layer 2.

In the photoelectric conversion element 1aa according to the twenty-third embodiment, the mesa portion 3 and the FD electrode 4 are shared by a plurality of pixels, the insulation layer 36 is disposed so as to penetrate the photoelectric conversion layer 2, and thus the planar shape is different from those in FIGS. 29B to 29E and FIGS. 30B to 30E. FIG. 31C is a cross-sectional view of a modification example of FIG. 31B.

In the photoelectric conversion element 1aa according to the twenty-third embodiment, for example, as illustrated in the plan view of FIG. 31B, the mesa portion 3 and the FD electrode 4 are disposed at the center portion of the 2×2 pixel, and four transfer gates 5 are disposed around the mesa portion 3. Alternatively, as illustrated in FIG. 31C, the mesa portion 3 may be disposed at an end portion of a boundary region between two adjacent pixels, and two transfer gates 5 may be disposed around the mesa portion 3.

### Twenty-Fourth Embodiment

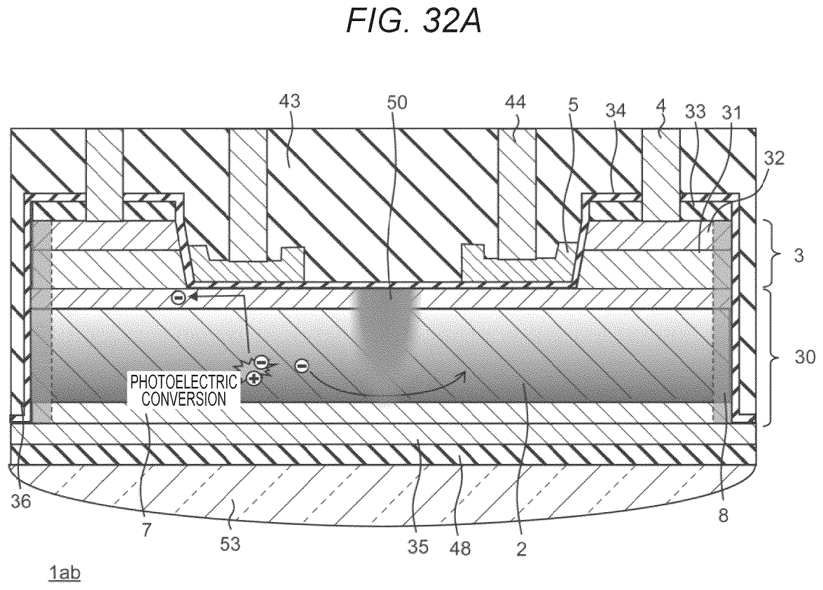

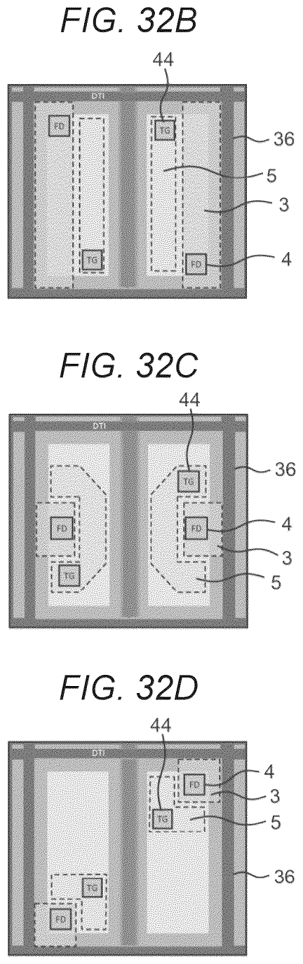

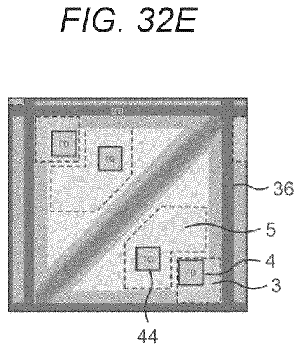

FIG. 32A is a cross-sectional view of a photoelectric conversion element 1ab according to a twenty-fourth embodiment, and FIG. 32B is a plan view. Similarly to the photoelectric conversion element 1y according to the twenty-first embodiment, the photoelectric conversion element 1ab according to the twenty-fourth embodiment can be used as a phase difference detection sensor. In the photoelectric conversion element 1ab according to the twenty-fourth embodiment, a diffusion layer 50 formed by implanting impurity ions is disposed in a pixel boundary region. The impurity ions are implanted from the upper surface side of the photoelectric conversion layer 2. The depth of the diffusion layer 50 can be adjusted by controlling the implantation amount of impurity ions and the heat treatment time. In the present embodiment, the read charge can be moved to the adjacent pixel through below the diffusion layer 50.

In the photoelectric conversion element 1ab according to the twenty-fourth embodiment, as illustrated in the plan view of FIG. 32B, the mesa portion 3 and the transfer gate 5, which have a rectangular shape along two opposite sides of the pixel, may be disposed. Alternatively, as described in a first modification example illustrated in FIG. 32C, the mesa portion 3 may be disposed at the center portion of two opposite sides of the pixel, and the transfer gate 5 may be disposed so as to surround the mesa portion 3. Alternatively, as illustrated in FIG. 32D, the mesa portions 3 may be disposed at diagonal corners of the pixel, and the transfer gates 5 may be disposed so as to surround the mesa portions 3. Alternatively, as illustrated in FIG. 32E, a pixel boundary may be provided in the diagonal direction of the pixel.

### Twenty-Fifth Embodiment

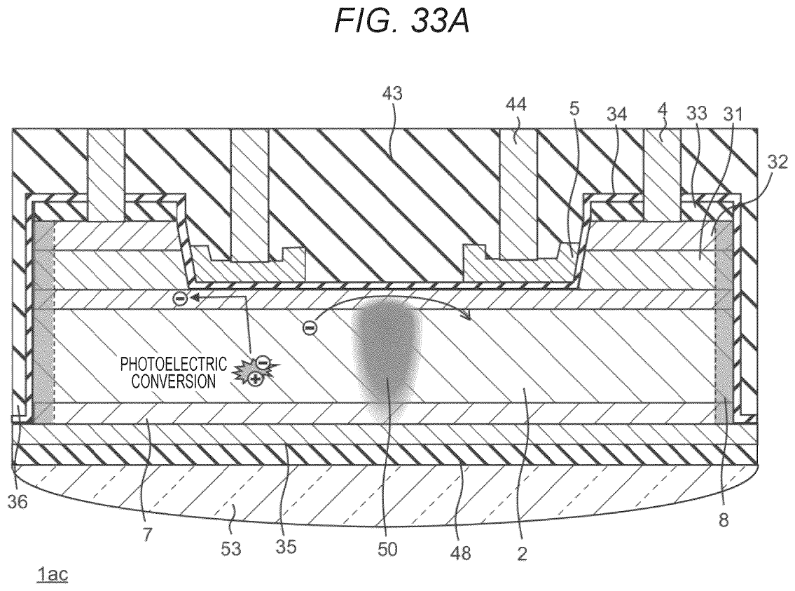

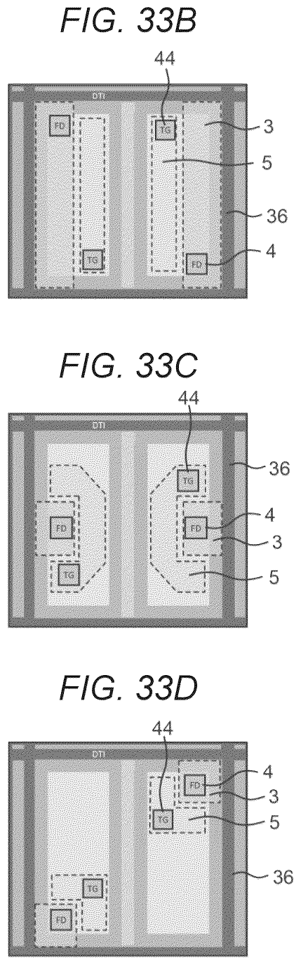

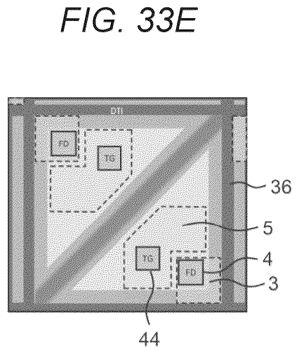

FIG. 33A is a cross-sectional view of a photoelectric conversion element 1ac according to a twenty-fifth embodiment, and FIG. 33B is a plan view. Similarly to the photoelectric conversion element 1y according to the twenty-first embodiment, the photoelectric conversion element 1ac according to the twenty-fifth embodiment can be used as a phase difference detection sensor. As in the twenty-fourth embodiment, in the photoelectric conversion element 1ac according to the twenty-fifth embodiment, a diffusion layer 50 formed by implanting impurity ions is disposed in a pixel boundary region. The impurity ions are implanted from the upper surface side of the photoelectric conversion layer 2, and the diffusion layer 50 is disposed up to a position deeper than that in FIG. 32A. Specifically, the diffusion layer 50 is disposed so as to penetrate the photoelectric conversion layer 2. The read charge overflowing from the pixel can move to the adjacent pixel through the p⁺-InGaAs layer 6 disposed on the upper surface of the photoelectric conversion layer 2. The diffusion layer 50 is formed by implanting impurity ions from above the photoelectric conversion layer 2 and performing heat treatment. It is necessary to perform control such that the impurity concentration of the p⁺-InGaAs layer 6 is not excessively high by controlling an implantation amount and implantation energy of the impurity ions. The p⁺-InGaAs layer 6 is used as an overflow path.

Various modification examples are conceivable for the planar shape of the photoelectric conversion element 1ac according to the twenty-fifth embodiment, and typical examples thereof are illustrated in FIGS. 33B to 33E. Since FIGS. 33B to 33E are similar to FIGS. 32B to 32E, detailed description will be omitted.

### Twenty-Sixth Embodiment

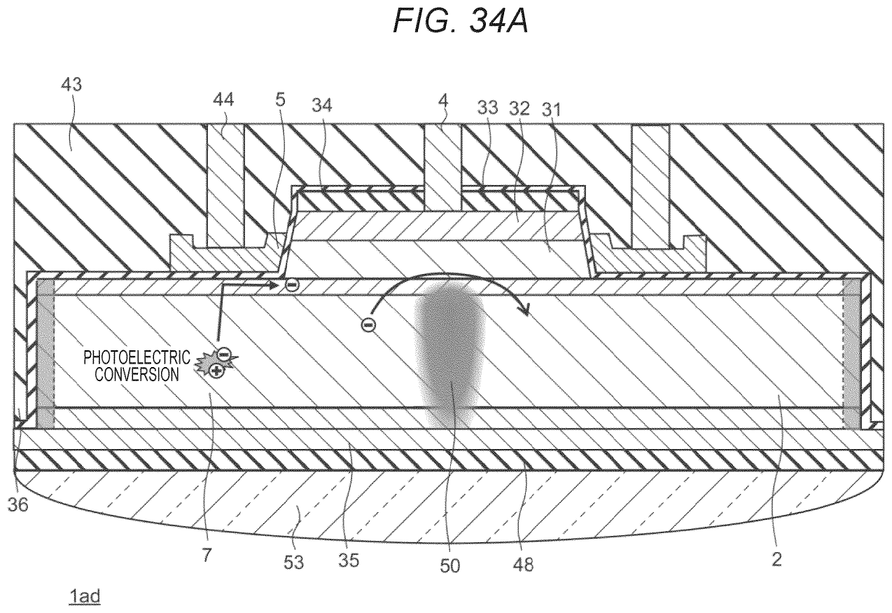

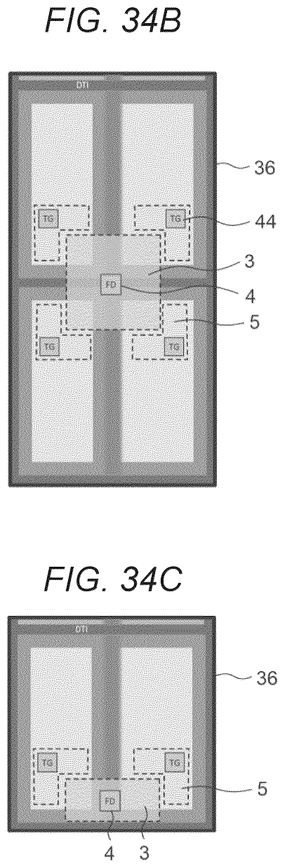

FIG. 34A is a cross-sectional view of a photoelectric conversion element 1ad according to a twenty-sixth embodiment, and FIGS. 34B to 34C are plan views. Similarly to the photoelectric conversion element 1y according to the twenty-first embodiment, the photoelectric conversion element 1ad according to the twenty-sixth embodiment can be used as a phase difference detection sensor.

The photoelectric conversion element 1ad of FIG. 34A is different from that in FIG. 33A in that the mesa portion 3 is disposed along the pixel boundary region. In the photoelectric conversion element 1ad of FIG. 34A, similarly to the photoelectric conversion element 1ac of FIG. 33A, the diffusion layer 50 at the pixel boundary is disposed so as to penetrate the photoelectric conversion layer 2. The read charge overflowing in the pixel can move to the adjacent pixel via the p-InP layer 31a in the mesa portion 3.

In the photoelectric conversion element 1ad according to the twenty-sixth embodiment, for example, as illustrated in FIG. 34B, the mesa portion 3 and the FD electrode 4 may be disposed at the center portion of a 2×2 pixel formed by pixels adjacent to each other, and the transfer gates 5 may be disposed around the mesa portion 3 and the FD electrode 4. Alternatively, as illustrated in FIG. 34C, the mesa portion 3 and the FD electrode 4 may be disposed at an end of the center portion of two pixels adjacent to each other, and the transfer gates 5 may be disposed around the mesa portion 3 and the FD electrode 4.

### Modification Example of First to Twenty-Sixth Embodiments

It is also possible to configure the photoelectric conversion element 1 or the like in which the characteristic portions of the photoelectric conversion element 1 and the like according to the first to twenty-sixth embodiments described above are arbitrarily combined. For example, a photoelectric conversion element including the photoelectric conversion layer 2 having an impurity concentration gradient as illustrated in FIG. 6 and the transfer gate 5 covering the entire upper surface of the photoelectric conversion layer 2 other than the mesa portion 3 as illustrated in FIG. 8 may be configured.

[Configuration Example of Imaging Device]

Next, an example of a specific configuration of an imaging device including a pixel array unit in which a plurality of photoelectric conversion elements 1 and the like according to the first to twenty-sixth embodiments described above is disposed will be described.

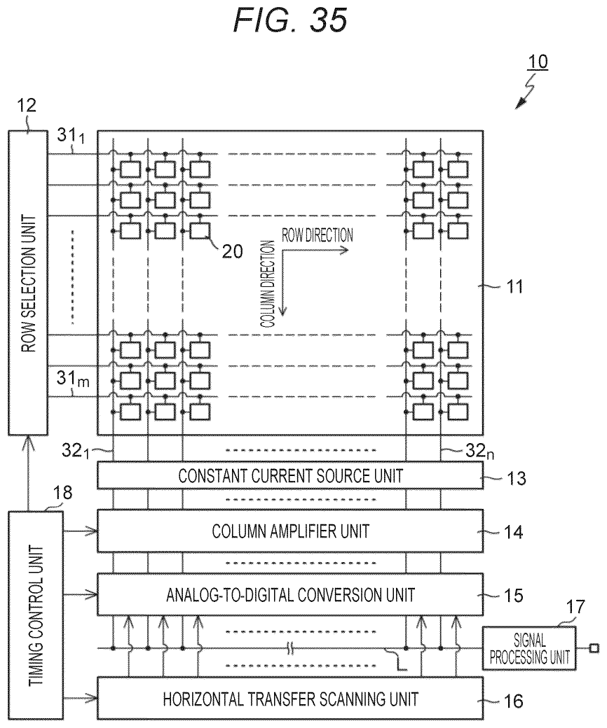

FIG. 35 is a block diagram illustrating an outline of a basic configuration of a CMOS image sensor which is an example of the imaging device to which the technology according to the present disclosure is applied.

A CMOS image sensor 10 according to this example includes a pixel array unit 11 and a peripheral circuit unit of the pixel array unit 11. In the pixel array unit 11, pixels (pixel circuits) 20 each including the photoelectric conversion element 1 are two-dimensionally disposed in a row direction and a column direction, that is, in a matrix. Here, the row direction refers to a direction in which the pixels 20 in a pixel row are arrayed, and the column direction refers to a direction in which the pixels 20 in a pixel column are arrayed. Each of the pixels 20 performs photoelectric conversion to generate and accumulate photoelectric charge corresponding to an amount of received light.

The peripheral circuit unit of the pixel array unit 11 includes, for example, a row selection unit 12, a constant current source unit 13, a column amplifier unit 14, an analog-to-digital conversion unit 15, a horizontal transfer scanning unit 16, a signal processing unit 17, and a timing control unit 18.

In the pixel array unit 11, pixel control lines 31₁ to 31ₘ are wired in the row direction for pixel rows, respectively, in a matrix pixel array. Furthermore, signal lines 32₁ to 32ₙ are wired in the column direction for pixel columns, respectively. Each of the pixel control lines 31₁ to 31ₘ transmits a drive signal for driving when reading a signal from the pixel 20. In FIG. 35, the pixel control lines 31₁ to 31ₘ are illustrated as one wire, but the number of the pixel control lines is not limited. One end of each of the pixel control lines 31₁ to 31ₘ is connected to an output end corresponding to each row of the row selection unit 12.

Hereinafter, components of the peripheral circuit unit of the pixel array unit 11, that is, the row selection unit 12, the constant current source unit 13, the column amplifier unit 14, the analog-to-digital conversion unit 15, the horizontal transfer scanning unit 16, the signal processing unit 17, and the timing control unit 18 will be described.

The row selection unit 12 includes a shift register and an address decoder, and controls scanning for the pixel row and an address of the pixel row when selecting each pixel 20 of the pixel array unit 11. Although a specific configuration of the row selection unit 12 is not illustrated, the row selection unit generally includes two scanning systems, for example, a read scanning system and a sweep scanning system.

The read scanning system sequentially and selectively scans the pixels 20 in the pixel array unit 11 row by row in order to read a pixel signal from the pixel 20. The pixel signal read from the pixel 20 is an analog signal. The sweep scanning system performs sweep scanning on a read row to be subjected to read scanning by the read scanning system earlier than the read scanning by a time corresponding to a shutter speed.

When the sweep scanning is performed by the sweep scanning system, unnecessary charge is swept from the photoelectric conversion elements 1 of the pixels 20 on the read row, and thus the photoelectric conversion elements 1 are reset. Then, when the sweep scanning system sweeps (resets) unnecessary charge, so-called electronic shutter operation is performed. Here, the electronic shutter operation refers to operation of discharging the photoelectric charge of the photoelectric conversion element 1 and newly starting exposure (starting accumulating the photoelectric charge).

The constant current source unit 13 supplies a bias current to each pixel column through each of the signal lines 21₁ to 21ₙ.

The column amplifier unit 14 includes a set of column amplifiers provided corresponding to the signal lines 21₁ to 21ₙ, respectively, for pixel columns. Then, each column amplifier of the column amplifier unit 14 amplifies the pixel signal read from each pixel 20 of the pixel array unit 11 and supplied through each of the signal lines 21₁ to 21ₙ, and supplies the amplified pixel signal to the analog-to-digital conversion unit 15.

The analog-to-digital conversion unit 15 is a column-parallel analog-to-digital conversion unit including a set of a plurality of analog-to-digital converters provided corresponding to the pixel columns of the pixel array unit 11 (for example, provided for pixel columns), respectively. The analog-to-digital conversion unit 15 converts an analog pixel signal output through each of the signal lines 21₁ to 21ₙ for each pixel column and amplified by the column amplifier unit 14 into a digital pixel signal.

The horizontal transfer scanning unit 16 includes a shift register and an address decoder, and controls scanning for the pixel column and an address of the pixel column when reading the signal of each pixel 20 of the pixel array unit 11. Under the control of the horizontal transfer scanning unit 16, the pixel signal converted into the digital signal by the analog-to-digital conversion unit 15 is read to a horizontal transfer line L in units of pixel column.

The signal processing unit 17 performs predetermined signal processing on the digital pixel signal supplied through the horizontal transfer line L to generate two-dimensional image data. For example, the signal processing unit 17 performs digital signal processing such as correction of a vertical line defect or correction of a point defect, parallel-to-serial conversion, compression, encoding, addition, averaging, and an intermittent operation. The signal processing unit 17 outputs the generated image data to a post-stage device as an output signal of this CMOS image sensor 10.

The timing control unit 18 generates various timing signals, clock signals, control signals, and the like, and performs drive control for the row selection unit 12, the constant current source unit 13, the column amplifier unit 14, the analog-to-digital conversion unit 15, the horizontal transfer scanning unit 16, the signal processing unit 17, and the like on the basis of the generated signals.

(Stacked Semiconductor Chip Structure)

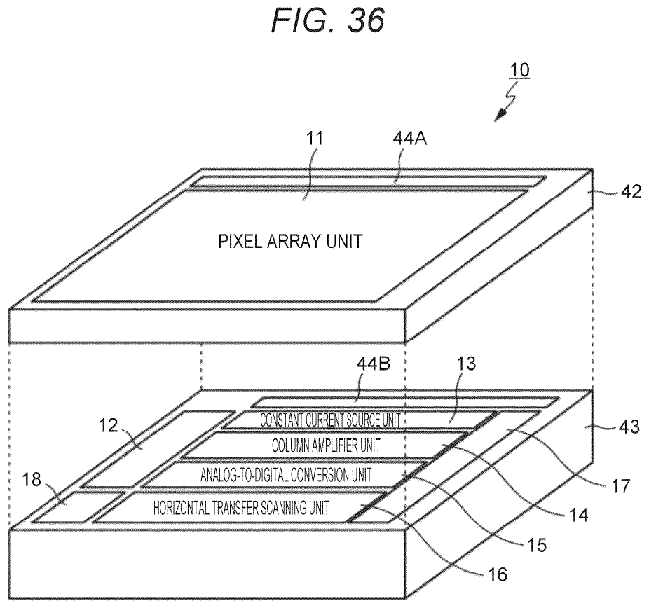

The CMOS image sensor of FIG. 35 can be realized by a semiconductor device including a plurality of stacked semiconductor chips. FIG. 36 is a schematic perspective view of a semiconductor device on which the CMOS image sensor of FIG. 35 is mounted. The semiconductor device illustrated in FIG. 36 has a structure in which at least two semiconductor chips (semiconductor substrates) of a first-layer semiconductor chip 22 and a second-layer semiconductor chip 23 are stacked. In this stacked structure, the pixel array unit 11 is formed on the first-layer semiconductor chip 22. Furthermore, the circuit portions such as the row selection unit 12, the constant current source unit 13, the column amplifier unit 14, the analog-to-digital conversion unit 15, the horizontal transfer scanning unit 16, the signal processing unit 17, and the timing control unit 18 are formed on the second-layer semiconductor chip 23. Then, the first-layer semiconductor chip 22 and the second-layer semiconductor chip 23 are electrically connected to each other by connection (VIA, bump, or the like) such as Cu—Cu connection.

In the CMOS image sensor 10 having the stacked structure, the first-layer semiconductor chip 22 is only required to have the size (area) enough to form the pixel array unit 11, and thus the size (area) of the first-layer semiconductor chip 22 and eventually the size of an entire chip can be reduced. Moreover, since a process suitable for fabricating the pixel 20 may be applied to the first-layer semiconductor chip 22 and a process suitable for fabricating the circuit portion may be applied to the second-layer semiconductor chip 23, there also is an advantage that the process may be optimized when the CMOS image sensor 10 is manufactured. In particular, an advanced process may be applied when the circuit portion is fabricated.

Note that, here, the stacked structure of two-layer structure formed by stacking the first-layer semiconductor chip 22 and the second-layer semiconductor chip 23 has been described as an example, but the stacked structure is not limited to the two-layer structure, and may be a structure of three or more layers. Then, in a case of the stacked structure of three or more layers, the circuit portions such the row selection unit 12, the constant current source unit 13, the column amplifier unit 14, the analog-to-digital conversion unit 15, the horizontal transfer scanning unit 16, the signal processing unit 17, and the timing control unit 18 can be formed by dispersing the circuit portions to the semiconductor chip of the second and subsequent layers.

### 4. Application Example

The technology according to the present disclosure can be applied to various products. For example, the technology according to the present disclosure may also be realized as a device mounted on any type of mobile body such as an automobile, an electric automobile, a hybrid electric automobile, a motorcycle, a bicycle, a personal mobility, an airplane, a drone, a ship, a robot, a construction machine, or an agricultural machine (tractor).

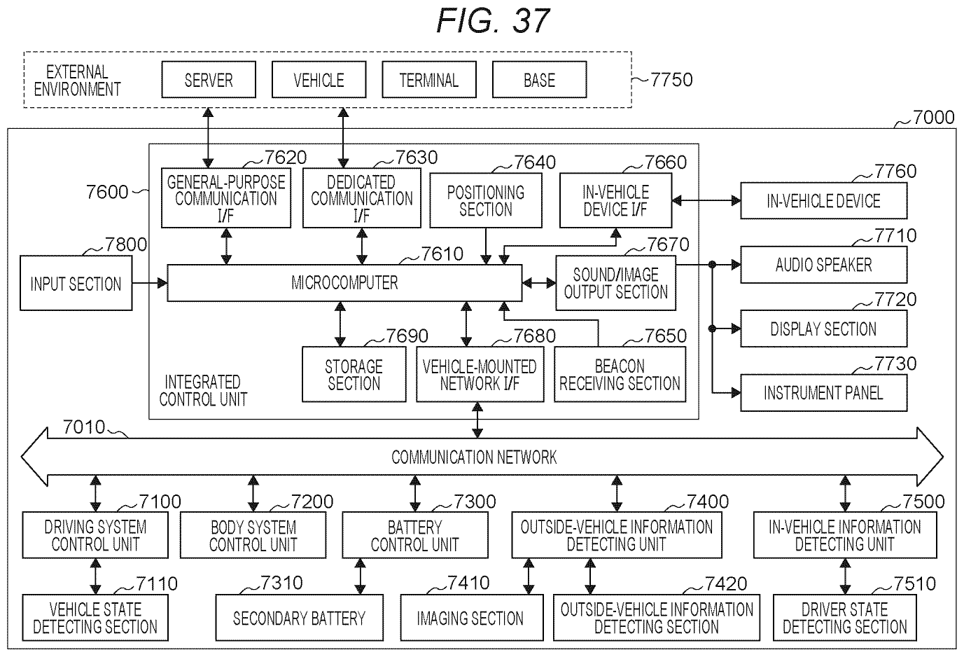

FIG. 37 is a block diagram illustrating a schematic configuration example of a vehicle control system 7000 as an example of a mobile body control system to which the technology according to the present disclosure can be applied. The vehicle control system 7000 includes a plurality of electronic control units connected to each other via a communication network 7010. In the example depicted in FIG. 37, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 37 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

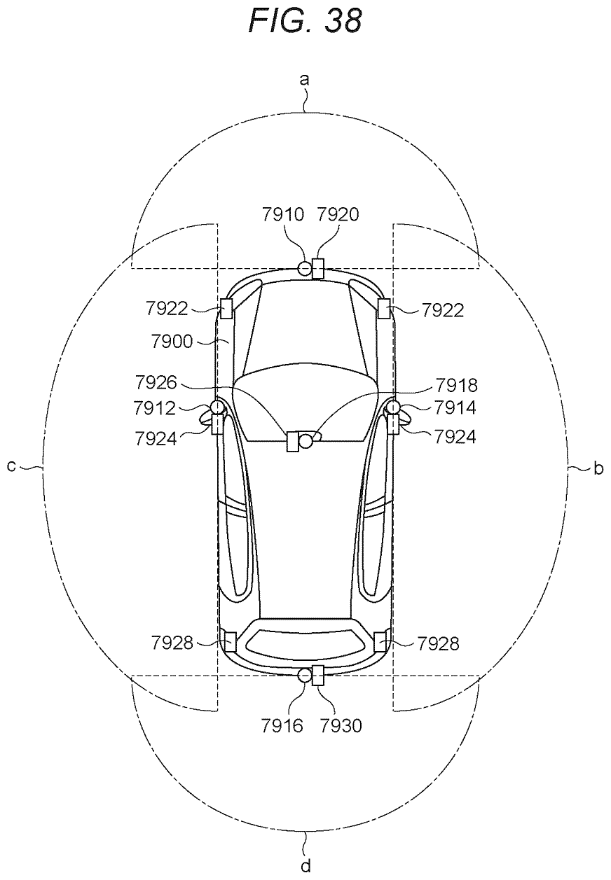

Here, FIG. 38 illustrates an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Note that FIG. 38 illustrates an example of an imaging range of each of the imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 37, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 37, an audio speaker 7710, a display section 7720, and an instrument panel 7730 are illustrated as output devices. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Note that in the example illustrated in FIG. 37, at least two control units connected to each other via the communication network 7010 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that the present technology may have the following configurations.
(1) A photoelectric conversion element including:
a photoelectric conversion layer including a compound semiconductor material;
a mesa portion disposed on a part of an upper surface side of the photoelectric conversion layer and including a compound semiconductor material having band gap energy larger than the band gap energy of the photoelectric conversion layer;
a first electrode disposed on the mesa portion and configured to read charge photoelectrically converted in the photoelectric conversion layer via the mesa portion; and
a transfer gate disposed to face a part of the upper surface side of the photoelectric conversion layer and at least a part of a sidewall of the mesa portion.
(2) The photoelectric conversion element according to (1), in which the mesa portion includes
a first semiconductor layer of a first conductivity type, and
a second semiconductor layer of a second conductivity type, which is stacked on the first semiconductor layer and connected to the first electrode, and
the first electrode reads charge of a second conductivity type, which is generated by photoelectric conversion in the photoelectric conversion layer.
(3) The photoelectric conversion element according to (2), further including a third semiconductor layer of a second conductivity type, which is disposed between the first electrode and the second semiconductor layer and has band gap energy smaller than the band gap energy of the first semiconductor layer and the band gap energy of the second semiconductor layer.
(4) The photoelectric conversion element according to (2) or (3), further including:
a fourth semiconductor layer disposed on the upper surface side of the photoelectric conversion layer and including an impurity of a first conductivity type;
a fifth semiconductor layer disposed on a lower surface side of the photoelectric conversion layer and including the impurity of the first conductivity type; and
a first diffusion layer disposed on a sidewall of the photoelectric conversion layer and including the impurity of the first conductivity type.
(5) The photoelectric conversion element according to (4), in which the fourth semiconductor layer is a semiconductor layer of a first conductivity type, which has band gap energy larger than the band gap energy of the photoelectric conversion layer.
(6) The photoelectric conversion element according to (4) or (5), in which the fifth semiconductor layer is disposed across a plurality of pixels without being separated at a boundary between the pixels.
(7) The photoelectric conversion element according to any one of (4) to (6), further including a second electrode disposed in a region where the mesa portion is not disposed on the upper surface side of the photoelectric conversion layer and electrically connected to the fifth semiconductor layer.
(8) The photoelectric conversion element according to any one of (1) to (7), further including an insulation film disposed along a boundary region between adjacent pixels of the photoelectric conversion layer.
(9) The photoelectric conversion element according to any one of (1) to (7), further including a light-shielding metal layer disposed along a boundary region between adjacent pixels of the photoelectric conversion layer.
(10) The photoelectric conversion element according to any one of (1) to (7), further including a second diffusion layer disposed along a boundary region between adjacent pixels of the photoelectric conversion layer and including an impurity of a first conductivity type.
(11) The photoelectric conversion element according to any one of (1) to (10), in which the photoelectric conversion layer has a lower concentration of an impurity of a first conductivity type on the upper surface side closer to the mesa portion and the transfer gate.
(12) The photoelectric conversion element according to any one of (1) to (11), in which the transfer gate is disposed to face an entire region where the mesa portion is not disposed on the upper surface side of the photoelectric conversion layer.
(13) The photoelectric conversion element according to any one of (1) to (12), in which the first electrode is disposed along a center portion, a corner portion, or one side of a pixel including the photoelectric conversion layer, the mesa portion, and the transfer gate.
(14) The photoelectric conversion element according to any one of (1) to (13), further including a third diffusion layer including an impurity of a first conductivity type, which is disposed in a region where the mesa portion is not disposed on the upper surface side of the photoelectric conversion layer.
(15) The photoelectric conversion element according to any one of (1) to (14), further including a fourth diffusion layer including an impurity of a first conductivity type, which is disposed on at least a part of the sidewall of the mesa portion.
(16) The photoelectric conversion element according to any one of (1) to (15), further including an insulation film disposed so as to cover at least a part of a periphery of the photoelectric conversion layer and mesa portion and having fixed charge having the same polarity as that of the charge read by the first electrode.
(17) The photoelectric conversion element according to any one of (1) to (16), further including an optical member disposed on a lower surface side of the photoelectric conversion layer and configured to condense light on the photoelectric conversion layer.
(18) The photoelectric conversion element according to any one of (1) to (17), in which one first electrode is shared by a plurality of pixels.
(19) The photoelectric conversion element according to any one of (1) to (18), further including a plurality of pixels each including the photoelectric conversion layer, the mesa portion, and the first electrode, the plurality of pixels being disposed adjacent to each other, in which charge photoelectrically converted in the photoelectric conversion layer is movable between the plurality of pixels, and a plurality of the first electrodes in the plurality of pixels sequentially reads the charge or the plurality of first electrodes reads the charge in parallel.
(20) An imaging device including a pixel array unit including a plurality of pixels,
in which each of the plurality of pixels includes:
a photoelectric conversion layer including a compound semiconductor material;
a mesa portion disposed on a part of an upper surface side of the photoelectric conversion layer and having band gap energy larger than the band gap energy of the photoelectric conversion layer;
a first electrode disposed on the mesa portion and configured to read charge photoelectrically converted in the photoelectric conversion layer via the mesa portion; and
a transfer gate disposed to face a part of the upper surface side of the photoelectric conversion layer and at least a part of a sidewall of the mesa portion.

Aspects of the present disclosure are not limited to the above-described embodiments, include various modifications that can be conceived by those skilled in the art, and the effects of the present disclosure are not limited to the above-described matters. That is, various additions, modifications, and partial deletions are possible without departing from the conceptual idea and spirit of the present disclosure derived from the matters defined in the claims and equivalents thereof.

### REFERENCE SIGNS LIST

1, 1a, 1b, 1c, 1d, 1e, 1f, 1g, 1h, 1i, 1j, 1k, 1m, 1n, 1o, 1p, 1q, 1r, 1s, 1t, 1u, 1v, 1w, 1x, 1y, 1z, 1aa, 1ab, 1ac, 1ad Photoelectric conversion element
2 Photoelectric conversion layer
2a p-InGaAs layer
2b n-InGaAs layer
3 Mesa portion
4 FD electrode
5 Transfer gate
6 InGaAs layer
6a InGaAs layer
6b InAlAs layer
7 InP layer
8, 8a Diffusion layer
10 CMOS image sensor
11 Pixel array unit
12 Row selection unit
13 Constant current source unit
14 Column amplifier unit
15 Analog-to-digital conversion unit
16 Horizontal transfer scanning unit
17 Signal processing unit
18 Timing control unit
20 Pixel
22, 23 Semiconductor chip
30 Photoelectric conversion portion
31 First semiconductor layer
31a p-InP layer
31b n-InP layer
31m Pixel control line
32 InP layer
32 Second semiconductor layer
32a InP layer
32b InP layer (second semiconductor layer)
32n Signal line
33, 34 Insulation film
35 Transparent electrode
36 Insulation layer
37 Stack structure
38 Insulation film
39 Trench
40 Insulation film
41 Resist
42 Metal film
43 Insulation film
44 Contact
46 Diffusion layer (third diffusion layer)
47 Diffusion layer (fourth diffusion layer)
48 Insulation film
49 Metal layer
50 Diffusion layer (second diffusion layer)
51 Insulation film
52 Third semiconductor layer
53 On-chip lens
100 Photoelectric conversion element
101 Photoelectric conversion layer
102 Zn diffusion layer
103 n-InP layer
104 Electrode
105 SiN layer
106 InP layer
107 Transparent electrode
110 Photoelectric conversion element
111 p-InGaAs layer (photoelectric conversion layer)
112 p-InP layer
113 InP layer
114 Electrode
115 SiN layer
116 Diffusion layer
117 Coating film
118 Protective film
119 InP layer
120 Transparent electrode
211 Signal line
311 Pixel control line
7000 Vehicle control system
7010 Communication network
7100 Driving system control unit
7110 Vehicle state detecting section
7200 Body system control unit
7300 Battery control unit
7310 Secondary battery
7400 Outside-vehicle information detecting unit
7410 Imaging section
7420 Outside-vehicle information detecting section
7500 In-vehicle information detecting unit
7510 Driver state detecting section
7600 Integrated control unit
7610 Microcomputer
7640 Positioning section
7650 Beacon receiving section
7670 Sound/image output section
7690 Storage section
7710 Audio speaker
7720 Display section
7730 Instrument panel
7750 External environment
7760 In-vehicle device
7800 Input section
7900 Vehicle
7910 Imaging section

1. A photoelectric conversion element comprising:
a photoelectric conversion layer including a compound semiconductor material;
a mesa portion disposed on a part of an upper surface side of the photoelectric conversion layer and including a compound semiconductor material having band gap energy larger than the band gap energy of the photoelectric conversion layer;
a first electrode disposed on the mesa portion and configured to read charge photoelectrically converted in the photoelectric conversion layer via the mesa portion; and
a transfer gate disposed to face a part of the upper surface side of the photoelectric conversion layer and at least a part of a sidewall of the mesa portion.

2. The photoelectric conversion element according to claim 1, wherein the mesa portion includes
a first semiconductor layer of a first conductivity type, and
a second semiconductor layer of a second conductivity type, which is stacked on the first semiconductor layer and connected to the first electrode, and
the first electrode reads charge of a second conductivity type, which is generated by photoelectric conversion in the photoelectric conversion layer.

3. The photoelectric conversion element according to claim 2, further comprising a third semiconductor layer of a second conductivity type, which is disposed between the first electrode and the second semiconductor layer and has band gap energy smaller than the band gap energy of the first semiconductor layer and the band gap energy of the second semiconductor layer.

4. The photoelectric conversion element according to claim 2, further comprising:
a fourth semiconductor layer disposed on the upper surface side of the photoelectric conversion layer and including an impurity of a first conductivity type;
a fifth semiconductor layer disposed on a lower surface side of the photoelectric conversion layer and including the impurity of the first conductivity type; and
a first diffusion layer disposed on a sidewall of the photoelectric conversion layer and including the impurity of the first conductivity type.

5. The photoelectric conversion element according to claim 4, wherein the fourth semiconductor layer is a semiconductor layer of a first conductivity type, which has band gap energy larger than the band gap energy of the photoelectric conversion layer.

6. The photoelectric conversion element according to claim 4, wherein the fifth semiconductor layer is disposed across a plurality of pixels without being separated at a boundary between the pixels.

7. The photoelectric conversion element according to claim 4, further comprising a second electrode disposed in a region where the mesa portion is not disposed on the upper surface side of the photoelectric conversion layer and electrically connected to the fifth semiconductor layer.

8. The photoelectric conversion element according to claim 1, further comprising an insulation film disposed along a boundary region between adjacent pixels of the photoelectric conversion layer.

9. The photoelectric conversion element according to claim 1, further comprising a light-shielding metal layer disposed along a boundary region between adjacent pixels of the photoelectric conversion layer.

10. The photoelectric conversion element according to claim 1, further comprising a second diffusion layer disposed along a boundary region between adjacent pixels of the photoelectric conversion layer and including an impurity of a first conductivity type.

11. The photoelectric conversion element according to claim 1, wherein the photoelectric conversion layer has a lower concentration of an impurity of a first conductivity type on the upper surface side closer to the mesa portion and the transfer gate.

12. The photoelectric conversion element according to claim 1, wherein the transfer gate is disposed to face an entire region where the mesa portion is not disposed on the upper surface side of the photoelectric conversion layer.

13. The photoelectric conversion element according to claim 1, wherein the first electrode is disposed along a center portion, a corner portion, or one side of a pixel including the photoelectric conversion layer, the mesa portion, and the transfer gate.

14. The photoelectric conversion element according to claim 1, further comprising a third diffusion layer including an impurity of a first conductivity type, which is disposed in a region where the mesa portion is not disposed on the upper surface side of the photoelectric conversion layer.

15. The photoelectric conversion element according to claim 1, further comprising a fourth diffusion layer including an impurity of a first conductivity type, which is disposed on at least a part of the sidewall of the mesa portion.

16. The photoelectric conversion element according to claim 1, further comprising an insulation film disposed so as to cover at least a part of a periphery of the photoelectric conversion layer and mesa portion and having fixed charge having a same polarity as that of the charge read by the first electrode.

17. The photoelectric conversion element according to claim 1, further comprising an optical member disposed on a lower surface side of the photoelectric conversion layer and configured to condense light on the photoelectric conversion layer.

18. The photoelectric conversion element according to claim 1, wherein one first electrode is shared by a plurality of pixels.

19. The photoelectric conversion element according to claim 1, further comprising a plurality of pixels each including the photoelectric conversion layer, the mesa portion, and the first electrode, the plurality of pixels being disposed adjacent to each other,
wherein charge photoelectrically converted in the photoelectric conversion layer is movable between the plurality of pixels, and a plurality of the first electrodes in the plurality of pixels sequentially reads the charge or the plurality of first electrodes reads the charge in parallel.

20. An imaging device comprising a pixel array unit including a plurality of pixels,
wherein each of the plurality of pixels includes:
a photoelectric conversion layer including a compound semiconductor material;
a mesa portion disposed on a part of an upper surface side of the photoelectric conversion layer and having band gap energy larger than the band gap energy of the photoelectric conversion layer;
a first electrode disposed on the mesa portion and configured to read charge photoelectrically converted in the photoelectric conversion layer via the mesa portion; and
a transfer gate disposed to face a part of the upper surface side of the photoelectric conversion layer and at least a part of a sidewall of the mesa portion.
